(19) United States
(12) Patent Application Publication
(10) Pub. No.: US 2023/0113565 A1
(43) Pub. Date: Apr. 13, 2023

(54) LIGHT-EMITTING DEVICE AND METHOD FOR MANUFACTURING SAME

(71) Applicant: SONY SEMICONDUCTOR SOLUTIONS CORPORATION, KANAGAWA (JP)

(72) Inventors: SHUNSUKE FURUSE, KANAGAWA (JP); HIROTAKA YOSHIOKA, KANAGAWA (JP)

(21) Appl. No.: 17/905,192

(22) PCT Filed: Feb. 1, 2021
(86) PCT No.: PCT/JP2021/003564

§ 371 Date: Aug. 29, 2022

(30) Foreign Application Priority Data
Mar. 6, 2020 (JP) 2020-039139

(51) Int. Cl. H01L 33/54; H01L 33/58; H01L 33/62

(52) U.S. Cl. CPC H01L 33/54; H01L 33/58; H01L 33/62; H01L 2933/005

(57) ABSTRACT

Provided is a light-emitting device and a method for manufacturing the same which allow the filling performance of the film that fills the space around light-emitting elements to be improved. The light-emitting device according to the disclosure includes a substrate, a plurality of light-emitting elements and a plurality of electrodes sequentially provided on a first surface of the substrate, and a film provided on the first surface of the substrate to surround the light-emitting elements, and when the first surface is a bottom surface of the substrate, the lowermost part of a bottom surface of the film is provided in a higher position than a bottom surface of the electrode. In this way, for example, the film is formed before the substrate is provided on another substrate, so that the filling performance of the film that fills the space around the light-emitting elements can be improved.

### TECHNICAL FIELD

The present disclosure relates to a light-emitting device and a method for manufacturing the same.

### BACKGROUND ART

A surface emitting laser such as a VCSEL (Vertical Cavity Surface Emitting Laser) is known as a type of semiconductor laser. In general, a light-emitting device with a surface emitting laser includes a plurality of light-emitting elements arranged in a two-dimensional array on the front or back surface of a substrate.

### CITATION LIST

### Patent Literature

[PTL 1]

JP 2008-227404 A

### SUMMARY

### Technical Problem

In the manufacture of a light-emitting device, a plurality of light-emitting elements as described above may be provided between two substrates, and the space around the light-emitting elements may be filled with a film such as an underfill film. This ensures connectivity or insulation between the elements of the light-emitting device between the substrates. However, if the filling performance of the film is poor, a filling defect such as a void can be generated between the substrates.

It is therefore an object of the present disclosure to provide a light-emitting device and a method for manufacturing the same which allow the filling performance of the film that fills the space around the light-emitting elements to be improved.

### Solution to Problem

A light-emitting device according to a first aspect of the disclosure includes a substrate, a plurality of light-emitting elements and a plurality of electrodes sequentially provided on a first surface of the substrate, and a film provided on the first surface of the substrate to surround the light-emitting elements, and when the first surface is a bottom surface of the substrate, the lowermost part of the bottom surface of the film is provided in a higher position than the bottom surface of the electrode. In this way, for example the film can be formed before the substrate is provided on another substrate, so that the filling performance of the film that fills the space around the light-emitting elements can be improved.

The light-emitting device according to the first aspect may further include a plurality of lenses provided on a second surface of the substrate as a part of the substrate on which light emitted from the light-emitting elements is incident. In this way, light from the light-emitting elements can be formed by the lenses.

According to the first aspect, the lenses may include at least one of a concave lens, a convex lens, and a flat lens. In this way, for example, light can be formed with an appropriate lens according to the intended use of the light.

According to the first aspect, the substrate may be a semiconductor substrate including gallium (Ga) and arsenic (As). In this way, the substrate can be suitable for the light-emitting elements.

According to the first aspect, the film may surround the light-emitting elements through an insulating film. In this way, for example, a conductive film can be prevented from contacting the light-emitting elements.

According to the first aspect, the film may be an insulating film. In this way, for example, short-circuiting between the elements of the light-emitting device provided at the first surface of the substrate can be suppressed.

According to the first aspect, the film may be an organic film or an inorganic film. In this way, for example, the film can be formed with an appropriate material for the intended use of the film.

According to the first aspect, the film may be a metal film. In this way, for example, the film can be used for heat dissipation.

According to the first aspect, the film may have a thermal conductivity higher than that of the substrate. In this way the film can be optimally used for heat dissipation.

According to the first aspect, the substrate may be provided on a second substrate, and the film does not have to be in contact with the second substrate. In this way, for example, the film can be formed before the substrate is provided on another substrate.

According to the first aspect, the second substrate may be a semiconductor substrate including silicon (Si). In this way, for example, the substrate can be provided on an inexpensively available second substrate.

The light-emitting device according to the first aspect may include a fill film provided between the film and the second substrate. In this way, for example, the elements of the light-emitting device which are not protected by the film can be protected by the fill film.

The light-emitting device according to the first aspect may further include a heat sink and a conductive adhesive provided between the heat sink and the film. In this way, the film can be used for heat dissipation together with the heat sink.

A method for manufacturing a light-emitting device according to a second aspect of the disclosure includes sequentially forming a plurality of light-emitting elements and a plurality of electrodes on a first surface of a substrate, and forming a film on the first surface of the substrate to surround the light-emitting elements, and when the first surface is an upper surface of the substrate, the uppermost part of the upper surface of the film is formed to be lower than the upper surface of the electrode. In this way, for example, the film can be formed before the substrate is provided on another substrate, so that the filling performance of the film that fills the space around the light-emitting elements can be improved.

The method for manufacturing a light-emitting device according to the second aspect may further include forming, on a second surface of the substrate, a plurality of lenses as a part of the substrate on which light emitted from the light-emitting devices is incident. In this way, light from the light-emitting elements can be formed with the lenses.

According to the second aspect, the lenses may include at least one of a concave lens, a convex lens, and a flat lens. In this way, for example, light can be formed with an appropriate lens for the intended use of the light.

According to the second aspect, the convex lens may be formed by forming a convex portion at the second surface of the second substrate. In this way, for example, the convex lens can be formed with a small number of man-hours.

A method for manufacturing a light-emitting device according to a third aspect of the disclosure includes sequentially forming a plurality of light-emitting elements and a plurality of electrodes on a first surface of a substrate, forming a film on the first surface of the substrate to surround the light-emitting elements, and providing the substrate on the second substrate after forming the film. In this way, the film can be formed before the substrate is provided on the second substrate, so that the filling performance of the film that fills the space around the light-emitting elements can be improved.

The method for manufacturing a light-emitting device according to the third aspect, when the first surface is an upper surface of the substrate, the uppermost part of the upper surface of the film may be formed to be lower than an upper surface of the electrode. In this way, for example, the electrode can be exposed through the film.

The method for manufacturing a light-emitting device according to the third aspect may further include forming, on a second surface of the substrate, a plurality of lenses as a part of the substrate on which light emitted from the light-emitting elements is incident. In this way, light from the light-emitting elements can be formed with the lenses.

### BRIEF DESCRIPTION OF DRAWINGS

FIG. 1 is a block diagram of a distance measuring device according to a first embodiment.

FIG. 2 is a cross-sectional view of an exemplary structure of the distance measuring device according to the first embodiment.

FIG. 3 is a cross-sectional view of the structure of the distance measuring device shown in FIG. 2 at B.

FIG. 4 is a cross-sectional view of the structure of a light-emitting device according to the first embodiment.

FIG. 5 is a plan view of the structure of the light-emitting device according to the first embodiment.

FIG. 6 is a cross-sectional view of the structure of a light-emitting device according to a comparative example with respect to the first embodiment.

FIG. 7 is a cross-sectional view of the structure of a light-emitting device according to a first modification of the first embodiment.

FIG. 8 is a cross-sectional view of the structure of a light-emitting device according to a second modification of the first embodiment.

FIG. 9 is a cross-sectional view of the structure of a light-emitting device according to a third modification of the first embodiment.

FIG. 10 is a cross-sectional view of the structure of a light-emitting device according to a fourth modification of the first embodiment.

FIG. 11 is a cross-sectional view of the structure of a light-emitting device according to a fifth modification of the first embodiment.

FIG. 12 is a cross-sectional view of the structure of a light-emitting device according to a sixth modification of the first embodiment.

FIG. 13 is a cross-sectional view (1/4) for illustrating a method for manufacturing a light-emitting device according to a second embodiment.

FIG. 14 is a cross-sectional view (2/4) for illustrating the method for manufacturing a light-emitting device according to the second embodiment.

FIG. 15 is a cross-sectional view (3/4) for illustrating the method for manufacturing a light-emitting device according to the second embodiment.

FIG. 16 is a cross-sectional view (4/4) for illustrating the method for manufacturing a light-emitting device according to the second embodiment.

FIG. 17 is a cross-sectional view for illustrating a method for manufacturing a light-emitting device according to a modification of the second embodiment.

FIG. 18 is a cross-sectional view for illustrating in detail the steps after the step shown in FIG. 16 at B.

FIG. 19 is a cross-sectional view for illustrating in detail the steps shown in FIG. 13 at A to C.

FIG. 20 is a cross-sectional view (1/2) for illustrating a method for manufacturing a light-emitting device according to a third embodiment.

FIG. 21 is a cross-sectional view (2/2) for illustrating the method for manufacturing a light-emitting device according to the third embodiment.

FIG. 22 is a cross-sectional view for illustrating the step shown in FIG. 21 at B.

FIG. 23 is a cross-sectional view for illustrating a method for manufacturing a light-emitting device according to a modification of the third embodiment.

FIG. 24 is a cross-sectional view for illustrating a method 1 different from the method shown in FIG. 20 at A to FIG. 21 at B.

FIG. 25 is a cross-sectional view for illustrating a method 2 different from the method shown in FIG. 20 at A to FIG. 21 at B.

FIG. 26 is a cross-sectional view of the structure of a light-emitting device according to a fourth embodiment.

FIG. 27 includes a cross-sectional view and a plan view of the structure of a light-emitting device according to a first modification of the fourth embodiment.

FIG. 28 is a cross-sectional view of the structure of a light-emitting device according to a second modification of the fourth embodiment.

FIG. 29 is a cross-sectional view of the structure of a light-emitting device according to a third modification of the fourth embodiment.

FIG. 30 is a cross-sectional view (1/4) for illustrating a method for manufacturing a light-emitting device according to a fifth embodiment.

FIG. 31 is a cross-sectional view (2/4) for illustrating the method for manufacturing a light-emitting device according to the fifth embodiment.

FIG. 32 is a cross-sectional view (3/4) for illustrating the method for manufacturing a light-emitting device according to the fifth embodiment.

FIG. 33 is a cross-sectional view (4/4) for illustrating the method for manufacturing a light-emitting device according to the fifth embodiment.

FIG. 34 is a cross-sectional view (1/4) for illustrating a method for manufacturing a light-emitting device according to a modification of the fifth embodiment.

FIG. 35 is a cross-sectional view (2/4) for illustrating the method for manufacturing a light-emitting device according to the modification of the fifth embodiment.

FIG. 36 is a cross-sectional view (3/4) for illustrating the method for manufacturing a light-emitting device according to the modification of the fifth embodiment.

FIG. 37 is a cross-sectional view (4/4) for illustrating the method for manufacturing a light-emitting device according to the modification of the fifth embodiment.

### DESCRIPTION OF EMBODIMENTS

Hereinafter, embodiments of the present disclosure will be described with reference to the drawings.

### First Embodiment

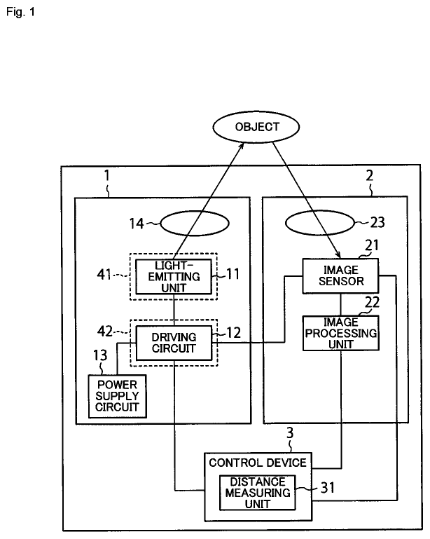

FIG. 1 is a block diagram of the structure of a distance measuring device according to a first embodiment.

The distance measuring device in FIG. 1 includes a light-emitting device 1, an image-sensing device 2, and a control device 3. The distance measuring device in FIG. 1 irradiates an object with light emitted from the light-emitting device 1, receives light reflected by the object by the image-sensing device 2 to capture an image of the object, and measures (calculates) the distance to the object by the control device 3 using an image signal output from the image-sensing device 2. The light-emitting device 1 functions as a light source for the image-sensing device 2 to capture an image of the object.

The light-emitting device 1 includes a light-emitting unit 11, a driving circuit 12, a power supply circuit 13, and a light-emitting side optical system 14. The image-sensing device 2 includes an image sensor 21, an image processing unit 22, and an image-sensing side optical system 23. The control device 3 includes a distance measuring unit 31.

The light-emitting unit 11 emits laser light to be directed upon an object. As will be described, the light-emitting unit 11 according to the embodiment includes a plurality of light-emitting elements arranged in a two-dimensional array, and each of the light-emitting elements has a VCSEL structure. Light emitted from these light-emitting elements is directed on the object. The light-emitting unit 11 according to the embodiment is provided in a chip called LD (Laser Diode) chip 41.

The driving circuit 12 is an electric circuit that drives the light-emitting unit 11. The power supply circuit 13 is an electrical circuit that generates power supply voltage for the driving circuit 12. The distance measuring device according to the embodiment generates the power supply voltage by the power supply circuit 13 for example from input voltage supplied from a battery in the distance measuring device and uses the power supply voltage to drive the light-emitting unit 11 by the driving circuit 12. The driving circuit 12 according to the embodiment is provided in a substrate referred to as an LDD (Laser Diode Driver) substrate 42.

The light-emitting side optical system 14 includes various optical elements and irradiates the object with light from the light-emitting unit 11 through these optical elements. Similarly, the image-sensing side optical system 23 includes various optical elements and receives light from the object through these optical elements.

The image sensor 21 receives light from the object through the image-sensing side optical system 23 and converts the light into an electrical signal by photoelectric conversion. The image sensor 21 may be a CCD (Charge Coupled Device) sensor or a CMOS (Complementary Metal Oxide Semiconductor) sensor. The image sensor 21 according to the embodiment converts the above-described electronic signal from the analog signal into a digital signal by A/D (Analog to Digital) conversion and outputs an image signal as a digital signal to the image processing unit 22. The image sensor 21 according to the embodiment also outputs a frame synchronization signal to the driving circuit 12, and the driving circuit 12 causes the light-emitting unit 11 to emit light in timing corresponding to the frame period in the image sensor 21 on the basis of the frame synchronization signal.

The image processing unit 22 performs various kinds of image processing on the image signal output from the image sensor 21. The image processing unit 22 includes for example an image processing processor such as a DSP (Digital Signal Processor).

The control device 3 controls various kinds of operation of the distance measuring device in FIG. 1 such as the light-emitting operation of the light-emitting device 1 and the image-sensing operation of the image-sensing device 2. The control device 3 may include a CPU (Central Processing Unit), a ROM (ROM Read Only Memory), and a RAM (Random Access Memory).

The distance measuring unit 31 measures the distance to the object on the basis of the image signal output from the image sensor 21 and processed by the image processing unit 22. The distance measuring unit 31 uses STL (Structured Light) method or ToF (Time of Flight) as a distance measuring method. The distance measuring unit 31 may measure the distance between the distance measuring device and the object for each part of the object on the basis of the image signal and specify the three-dimensional shape of the object.

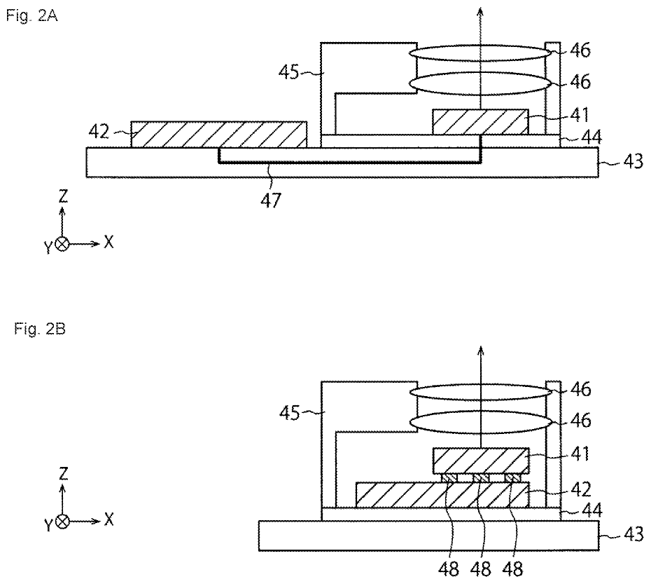

FIG. 2 is a cross-sectional view of an exemplary structure of the distance measuring device according to the first embodiment.

FIG. 2 at A shows a first example of the structure of the distance measuring device according to the embodiment. In this example, the distance measuring device includes the LD chip 41 and an LDD substrate 42, a mounting substrate 43, a heat dissipation substrate 44, a correction lens holder 45, at least one correction lens 46, and a wiring 47.

As shown in FIG. 2 at A, the X-, Y-, and Z-axes are perpendicular to each other. The X- and Y-directions correspond to the transverse direction (horizontal direction) and the Z-direction corresponds to the longitudinal (vertical) direction. The +Z direction corresponds to the upward direction, and the −Z direction corresponds to the downward direction. The −Z direction may or may not strictly coincide with the gravity direction.

The LD chip 41 is provided on the mounting substrate 43 through the heat dissipation substrate 44. The LDD substrate 42 is also provided on the mounting substrate 43. The mounting substrate 43 may be a printed circuit board. The image sensor 21 and the image processing unit 22 in FIG. 1 are also provided at the mounting substrate 43. The heat dissipation substrate 44 may be a ceramic substrate such as an AlN (aluminum nitride) substrate.

The correction lens holder 45 is provided on the heat dissipation substrate 44 to surround the LD chip 41 and holds one or more correction lenses 46 above the LD chip 41. These correction lenses 46 are included in the light-emitting side optical system 14 (FIG. 1). Light emitted from the light-emitting unit 11 (FIG. 1) in the LD chip 41 is corrected by the correction lenses 46 and then directed on the object (FIG. 1). FIG. 2 at A shows two correction lenses 46 held by the correction lens holder 45 by way of example.

The wiring 47 is provided for example on the front surface, the back surface, and inside of the mounting substrate 41 to electrically connect the LD chip 41 and the LDD substrate 42. The wiring 47 may be a printed wiring provided on the front or back surface of the mounting substrate 41 or a via wiring through the mounting substrate 41. The wiring 47 according to the embodiment is further passed through or near the heat dissipation substrate 44.

FIG. 2 at B shows a second example of the structure of the distance measuring device according to the embodiment. In this example, the distance measuring device includes the same components as the first example of the distance measuring device but has bumps 48 instead of the wiring 47.

As shown in FIG. 2 at B, the LDD substrate 42 is provided on the heat dissipation substrate 44 and the LD chip 41 is provided on the LDD substrate 42. The LD chip 41 is provided on the LDD substrate 42 in this manner, so that the size of the mounting substrate 44 can be made smaller than that in the first example. As shown in FIG. 2 at B, the LD chip 41 is provided on the LDD substrate 42 through the bumps 48 and is electrically connected to the LDD substrate 42 through the bumps 48.

In the following description, the distance measuring device according to the embodiment has the structure of the second example shown in FIG. 2 at B. However, the following description may also be applied to the distance measuring device having the structure of the first example, except for the description of the structure specific to the second example.

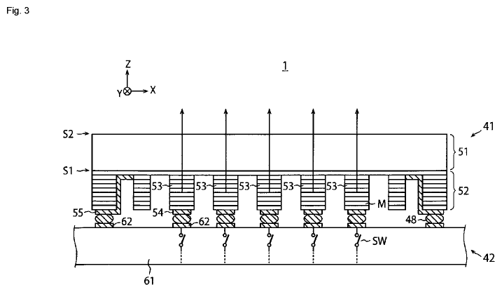

FIG. 3 is a cross-sectional view of the structure of the distance measuring device shown in FIG. 2 at B.

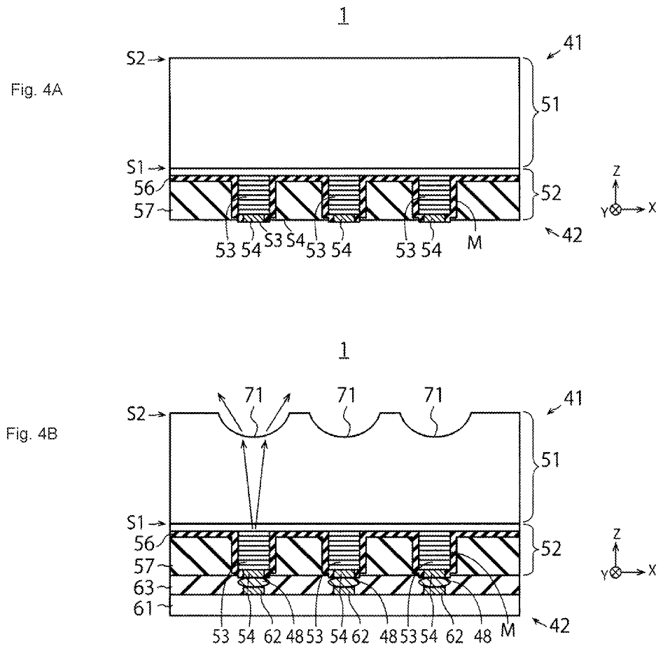

FIG. 3 shows a cross-section of the LD chip 41 and the LDD substrate 42 in the light-emitting device 1. As shown in FIG. 3, the LD chip 41 includes a substrate 51, a laminated film 52, a plurality of light-emitting elements 53, a plurality of anode electrodes 54, and a plurality of cathode electrodes 55. The LDD substrate 42 includes a substrate 61 and a plurality of connection pads 62. In FIG. 3, lenses 71 and the like which will be described are not shown (see FIG. 4).

The substrate 51 is a semiconductor substrate such as a GaAs (gallium arsenide) substrate. FIG. 3 shows the front surface S1 of the substrate 51 facing the −Z direction and the back surface S2 of the substrate 51 facing the +Z direction. The front surface S1 is an example of the first surface according to the disclosure. The back surface S2 is an example of the second surface according to the present disclosure.

The laminated film 52 includes a plurality of layers placed on the front surface S1 of the substrate 51. Examples of these layers include an n-type semiconductor layer, an active layer, a p-type semiconductor layer, a light reflecting layer, and an insulating layer with a light emission window. The laminated film 52 includes a plurality of mesa portions M which protrude in the −Z direction. Some of the mesa portions M form the plurality of light-emitting elements 53.

The plurality of light-emitting elements 53 are a part of the laminated film 52 and provided on the front surface S1 of the substrate 52. The light-emitting elements 53 according to the embodiment each have a VCSEL structure and emits light in the +Z direction. As shown in FIG. 3, the light emitted from each of the light-emitting elements 53 passes through the substrate 51 from the front surface S1 to the back surface S2 and then enters the correction lens 46 (FIG. 2) from the substrate 51. In this way, the LD chip 41 according to the embodiment is a back-illuminated VCSEL chip.

The anode electrodes 54 are formed on the bottom surfaces of the light-emitting elements 53. Therefore, the light-emitting elements 53 and the anode electrodes 54 are provided sequentially on the front surface S1 of the substrate 51. The cathode electrodes 55 are formed on the bottom surfaces of the mesa portions M excluding the location of the light-emitting elements 53 and extend to the bottom surface of the laminated film 52 between the mesa portions M. Each of the light-emitting elements 53 emits light when current flows between its anode electrode 54 and a corresponding cathode electrode 55. The anode electrode 54 is an example of the electrode according to the present disclosure.

As described above, the LD chip 41 is provided on the LDD substrate 42 through the bumps 48 and electrically connected with the LDD substrate 42 through the bumps 48. Specifically, the connection pads 62 are formed on the substrate 61 included in the LDD substrate 42, and the mesa portions M are provided on the connection pads 62 through the bumps 48. Each of the mesa portions M is provided on a bump 48 through the anode electrode 54 or the cathode electrode 55. The substrate 61 is a semiconductor substrate such as a Si (silicon) substrate. The substrate 61 is an example of the second substrate according to the present disclosure.

The LDD substrate 42 includes the driving circuit 12 that drives the light-emitting unit 11 (FIG. 1). FIG. 3 schematically shows a plurality of switches SW included in the driving circuit 12. The switches SW are each electrically connected to a light-emitting element 53 corresponding thereto through a bump 48. The driving circuit 12 according to the embodiment can control (turn on/off) the switches SW individually. Therefore, the driving circuit 12 can drive the plurality of light-emitting elements 53 individually. This allows light emitted from the light-emitting unit 11 to be accurately controlled, so that for example only the light-emitting element 53 necessary for distance measurement is allowed to emit light. Such individual control of the light-emitting elements 53 can be carried out by providing the LDD substrate 42 under the LD chip 41, so that the light-emitting elements 53 can be more easily electrically connected to the corresponding switches SW.

FIG. 4 is a cross-sectional view of the structure of the light-emitting device 1 according to the first embodiment.

FIG. 4 at A shows the LD chip 41 before being provided on the LDD substrate 42 and illustrates the light-emitting device 1 yet to be completed. Meanwhile, FIG. 4 at B shows the LD chip 41 provided on the LDD substrate 42 and illustrates the light-emitting device 1 in a completed form. The structure of the light-emitting device 1 according to the first embodiment will be described with reference to FIG. 4 at B. In the following description, FIG. 4 at A will also be referred to as appropriate.

FIG. 4 at B is a cross section of the LD chip 41 and the LDD substrate 42 in the light-emitting device 1. As described above, the LD chip 41 includes the substrate 51, the laminated film 52, the plurality of light-emitting elements 53, the plurality of anode electrodes 54, and the plurality of cathode electrodes 55, and the LDD substrate 42 includes the substrate 61 and the plurality of connection pads 62. However, in FIG. 4 at B, the cathode electrodes 55 are not shown.

The LD chip 41 according to the embodiment includes a plurality of light-emitting elements 53 at the front surface S1 of the substrate 51 and the plurality of lenses 71 at the back surface S2 of the substrate 51. These lenses 71 are arranged in a two-dimensional array similarly to the light-emitting elements 53. The lenses 71 according to the embodiment are arranged one-to-one with respect to the light-emitting elements 53, and each of the lenses 71 is provided in the +Z direction with respect to a single light-emitting element 53.

The lenses 71 according to the embodiment are provided at the back surface S2 of the substrate 51 as a part of the substrate 51. Specifically, the lenses 71 according to the embodiment are concave lenses which are formed as a part of the substrate 51 by etching the back surface S2 of the substrate 51 into a concave shape. According to the embodiment, the lenses 71 can be easily formed by processing the substrate 51. The lenses 71 according to the embodiment are formed after the LD chip 41 is provided on the LDD substrate 42 as shown in FIG. 4 at A and B.

Light emitted from the plurality of light-emitting elements 53 passes through the substrate 51 from the front surface S1 to the back surface S2 and enters the plurality of lenses 71. According to the embodiment, as shown in FIG. 4 at B, the light emitted from each of the light-emitting elements 53 is incident on one corresponding lens 71. This allows the light emitted from each light-emitting element 53 to be shaped by the corresponding lens 71. The light passed through the lenses 71 passes through the correction lenses 46 (FIG. 2) and is directed upon the object (FIG. 1).

The light-emitting device 1 according to the embodiment further includes an insulating film 56 and an organic film 57 provided before the LD chip 41 is provided on the LDD substrate 42 and an underfill film 63 provided after the LD chip 41 is provided on the LDD substrate 42. The organic film 57 is an example of the film according to the present disclosure. The underfill film 63 is an example of the fill film according to the present disclosure.

The insulating film 56 and the organic film 57 are provided on the front surface S1 of the substrate 51 to surround the mesa portions M such as light-emitting elements 53. Specifically, the insulating film 56 is formed on the bottom surface of the laminated film 52 and on the side surfaces of the mesa portions M and functions for example as a passivation film. Also, the organic film 57 is formed on the bottom surface of the laminated film 52 and the side surfaces of the mesa portions M through the insulating film 56.

FIG. 4 at A shows the surface (bottom surface) S3 of the anode electrode 54 and the surface (bottom surface) S4 of the organic film 57. In the LD chip 41 shown in FIG. 4 at A, the front surface S1 of the substrate 51 faces down, and the back surface S2 of the substrate 51 faces up. According to the embodiment, when the front surface S1 is the bottom surface of the substrate 51, the lowermost part (lowest part) of the surface S4 of the organic film 57 is provided in a higher position than the surface S3 of the anode electrode 54. Specifically, since the surface S4 of the organic film 57 in FIG. 4 at A is a flat surface, the entire surface S4 of the organic film 57 is the lowermost part of the surface S4 of the organic film 57, and the entire surface S4 of the organic film 57 is provided in a higher position than the surface S3 of the anode electrode 54. According to the embodiment, since the organic film 57 is formed before the LD chip 41 is provided on the LDD substrate 42, the entire surface S4 of the organic film 57 can be set in a higher position than the surface S3 of the anode electrode 54. In this way, for example, the anode electrodes 54 can be exposed through the organic film 57, so that the anode electrodes 54 can be brought into contact with the bumps 48.

The organic film 57 is an insulating film according to the embodiment while the organic film may be either an insulating film or a non-insulating film since the organic film is electrically insulated from the laminated film 52, the light-emitting elements 53, the anode electrodes 54, and the like by the insulating film 56. Therefore, according to the embodiment, the insulating film 56 and the organic film 57 are formed on the front surface S1 of the substrate 51, so that short circuiting between the elements of the light-emitting device 1 provided on the front surface S1 of the substrate 51 can be reduced. For example, short-circuiting between the light-emitting elements 53 adjacent to each other or between the anode electrodes 54 thereof can be suppressed. Furthermore, according to the embodiment, the elements of the light-emitting device 1 provided on the front surface S1 of the substrate 51 can be protected by the insulating film 56 and the organic film 57. For example, the anode electrodes 54 and the cathode electrodes 55 can be suppressed from coming off from the mesa portions M.

The organic film 57 may be made of a migration-resistant organic material. An example of the organic film 57 is a resin film of phenol resin or polyimide resin. The organic film 57 according to the embodiment is desirably made of an organic material with high sealing performance, pressure resisting performance, and water resisting performance. According to the embodiment, the organic film 57 may include a filler to enhance the heat dissipation of the organic film 57.

The underfill film 63 may be an insulating film. As shown in FIG. 4 at B, the underfill film 63 is formed between the organic film 57 and the substrate 61 to surround the bumps 48 and the like. In this way, the elements of the light-emitting device 1 that are not protected by the insulating film 56 or the organic film 57 can be protected by the underfill film 63. For example, this ensures connectivity between the anode electrodes 54, the cathode electrodes 55, and the connection pads 62 and the bumps 48 and insulation between the bumps 48 adjacent to each other. The underfill film 63 according to the embodiment is formed as the underfill film 63 is filled between the organic film 57 and the substrate 61 after the LD chip 41 is provided on the LDD substrate 42. The organic film 57 according to the embodiment is not in contact with the substrate 61 and is provided on the substrate 61 through the underfill film 63.

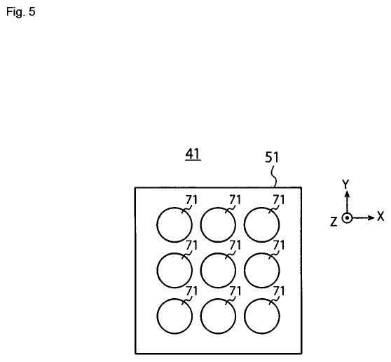

FIG. 5 is a plan view of the structure of the light-emitting device 1 according to the first embodiment.

FIG. 5 shows an exemplary layout of the lenses 71 shown in FIG. 4 at B. In FIG. 5, 3×3 lenses 71 are arranged on the back surface S2 of the substrate 51 in a two-dimensional array, specifically, in a square lattice. Each of lenses 71 is provided in the +Z direction of the corresponding light-emitting element 53 (FIG. 4 at B). The number of the lenses 71 of the light-emitting device 1 according to the embodiment may be arbitrary, and the arrangement of the lenses 71 of the light-emitting device 1 according to the embodiment may be in a different arrangement from the square lattice.

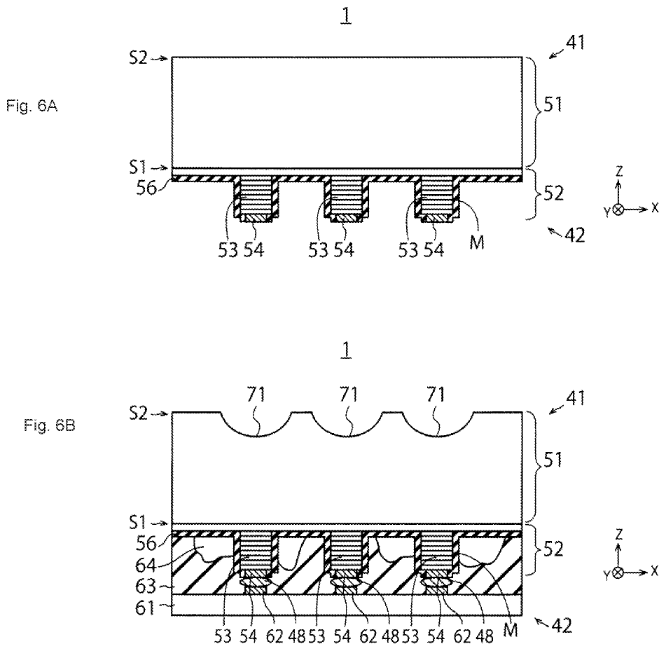

FIG. 6 is a cross-sectional view of the structure of the light-emitting device 1 in a comparative example with respect to the first embodiment.

FIG. 6 at A shows the LD chip 41 before being provided on the LDD substrate 42 and illustrates the light-emitting device 1 yet to be completed. Meanwhile, FIG. 6 at B shows the LD chip 41 provided on the LDD substrate 42 and illustrates the light-emitting device 1 in a completed form.

The light-emitting device 1 in this comparative example does not have the organic film 57 as shown in FIG. 6 at A. Therefore, as shown in FIG. 6 at B, the underfill film 63 in this comparative example is filled within a large area between the insulating film 56 and the substrate 61. Therefore, unsuccessful filling of the underfill film 63 may result in a filling defect such as a void 64 between the insulating film 56 and the substrate 61. One possible cause of such a filling defect is that the light-emitting elements 53 and the like densely provided between the substrates 51 and 61 interfere with filling of the underfill film 63. If a large void 64 is formed, the light-emitting elements 53 in the vicinity of the voids 64 can be protected only by the insulating film 56, which could lower the reliability of the light-emitting elements 53.

Also, the substrate 51 in the comparative example may be a GaAs substrate. The GaAs substrate is advantageous in that the substrate is suitable for forming the light-emitting elements 53 but is disadvantages because the substrate is a compound semiconductor substrate and is not strong enough. Therefore, the substrate 51 may be damaged, for example cracked or chipped during the manufacture of the light-emitting device 1. Damage to the substrate 51 may occur, for example, when the substrate 51 is made thinner, when the lenses 71 are formed or when the LD chip 41 (substrate 51) is provided on the LDD substrate 42 (substrate 61). Furthermore, the presence of the void 64 as described above between the substrates 51 and 61 may cause the strength of the LD chip 41 to be unequal, which makes the substrate 51 even more susceptible to damage. In addition, in order to reduce the voids 64, for example, the LD chip 41 and the LDD substrate 42 may be bonded with a high load, but the bonding under a high load can easily damage the substrate 51.

Meanwhile, as shown in FIG. 4 at A, the light-emitting device 1 according to the embodiment has the organic film 57 provided before the LD chip 41 is provided on the LDD substrate 42. Therefore, as shown in FIG. 4 at B, the underfill film 63 according to the embodiment is filled within a small area between the organic film 57 and the substrate 61. Therefore, according to the embodiment, the filling defect such as the voids 64 between the organic film 57 and the substrate 61 can be suppressed. The organic film 57 according to the embodiment is not filled between the substrates 51 and 61 after the LD chip 41 is provided on the LDD substrate 42 but the film is formed on the front surface Si of the substrate 51 before the LD chip 41 is provided on LDD substrate 42. In this way, the filling defect such as the voids 64 between the insulating film 56 and the organic films 57 can be suppressed.

The substrate 51 according to the embodiment may also be a GaAs substrate. As described above, the GaAs substrate is advantageous in that the substrate is suitable for forming the light-emitting element 53 but disadvantages in terms of strength. However, according to the embodiment, the voids 64 can be reduced, so that a reduction in the strength of the LD chip 41 attributable to the voids 64 can be suppressed, and damage to the substrate 51 during the manufacture of the light-emitting device 1 can be reduced. In addition, according to the embodiment, for example after the organic film 57 is formed, the surface of the organic film 57 may be planarized for example by CMP (Chemical Mechanical Polishing) to expose the anode electrodes 54 through the organic film 57. This allows the thickness of the organic film 57 to be uniform and the voids 64 to be suppressed without bonding with a high load as described above. This also contributes to reduction of damage to the substrate 51.

In this way, according to the embodiment, the organic film 57 is formed before the LD chip 41 is provided on the LDD substrate 42, so that the filling performance of the films that fill the space surrounding the light-emitting elements 53 can be improved. According to the embodiment, the space around the light-emitting elements 53 is filled with the insulating film 56 and the organic film 57, and the remaining space between the substrates 51 and 61 is filled with the underfill film 63. In this way, the voids 64 can be reduced and damage to the substrate 51 can be reduced. Therefore, according to the embodiment, the disadvantage of the GaAs substrate can be reduced while the advantage of the GaAs substrate can be enjoyed.

Note that the substrate 51 according to the embodiment may be a GaAs substrate, while the substrate 61 may be a Si substrate. When the Si substrate is used as the substrate 61, the substrate 61 may be prepared less costly.

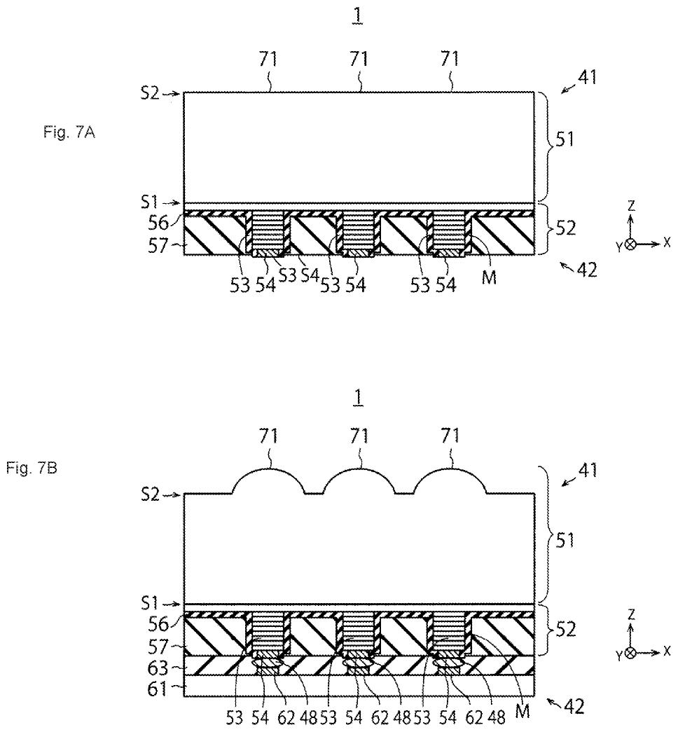

FIG. 7 is a cross-sectional view of the structure of the light-emitting device 1 according to a first modification of the first embodiment.

FIG. 7 at A shows the LD chip 41 before being provided on the LDD substrate 42 and illustrates the light-emitting device 1 yet to be completed. Meanwhile, FIG. 7 at B shows the LD chip 41 provided on the LDD substrate 42 and illustrates the light-emitting device 1 in a completed form.

The lenses 71 according to the modification are convex lenses. The lenses 71 according to the modification are also formed at the back surface S2 of the substrate 51 as a part of the substrate 51. The light emitted from each of the light-emitting elements 53 passes through the substrate 51 from the front surface S1 to the back surface S2 and is incident on the corresponding lens 71.

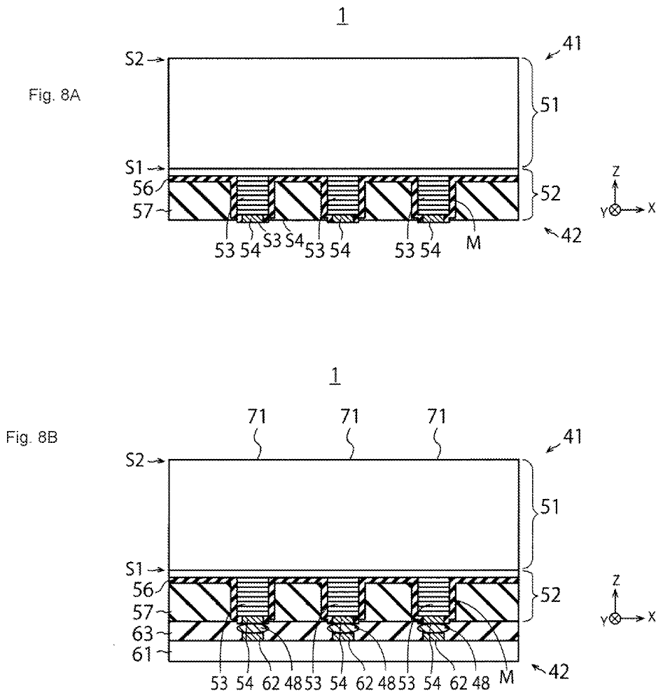

FIG. 8 is a cross-sectional view of the structure of the light-emitting device 1 according to a second modification of the first embodiment.

FIG. 8 at A shows the LD chip 41 before being provided on the LDD substrate 42 and illustrates the light-emitting device 1 yet to be completed. Meanwhile, FIG. 8 at B shows the LD chip 41 provided on the LDD substrate 42 and illustrates the light-emitting device 1 in a completed form.

The lenses 71 according to the modification are flat lenses. The flat lens has a flat surface and a flat lens surface is provided directly above a corresponding light-emitting element 53. Light from the corresponding light-emitting element 53 is incident on the flat lens surface. The presence of the flat lens above the light-emitting element 53 can also be considered as a state with no lens above the light-emitting element 53. The lenses 71 according to the modification are also formed on the back surface S2 of the substrate 51 as a part of the substrate 51.

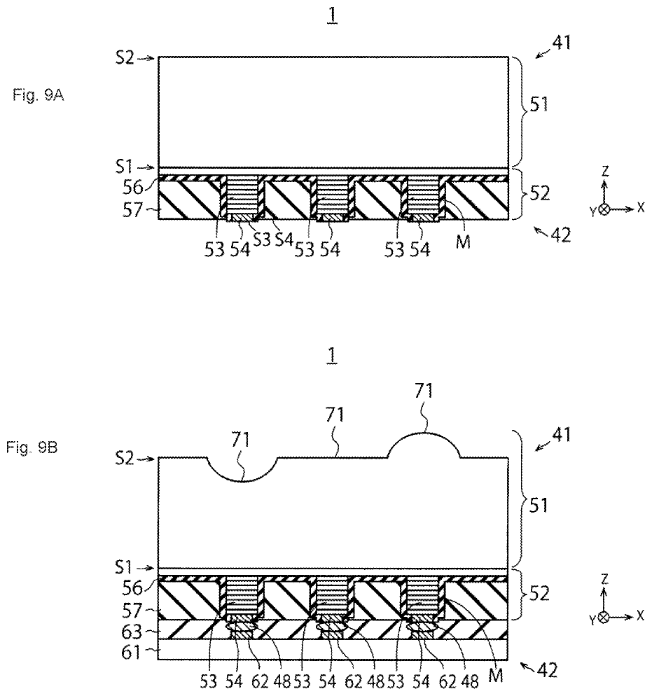

FIG. 9 is a cross-sectional view of the structure of the light-emitting device 1 according to a third modification of the first embodiment.

FIG. 9 at A shows the LD chip 41 before being provided on the LDD substrate 42 and illustrates the light-emitting device 1 yet to be completed. Meanwhile, FIG. 9 at B shows the LD chip 41 provided on the LDD substrate 42 and illustrates the light-emitting device 1 in a completed form.

The lenses 71 according to the modification include at least two kinds of lenses and may include a concave lens, a flat lens, and a convex lens. The lenses 71 according to the modification are also formed on the back surface S2 of the substrate 51 as a part of the substrate 51. Light emitted from each of the light-emitting elements 53 passes through the substrate 51 from the front surface S1 to the back surface S2 and is incident on a corresponding lens 71.

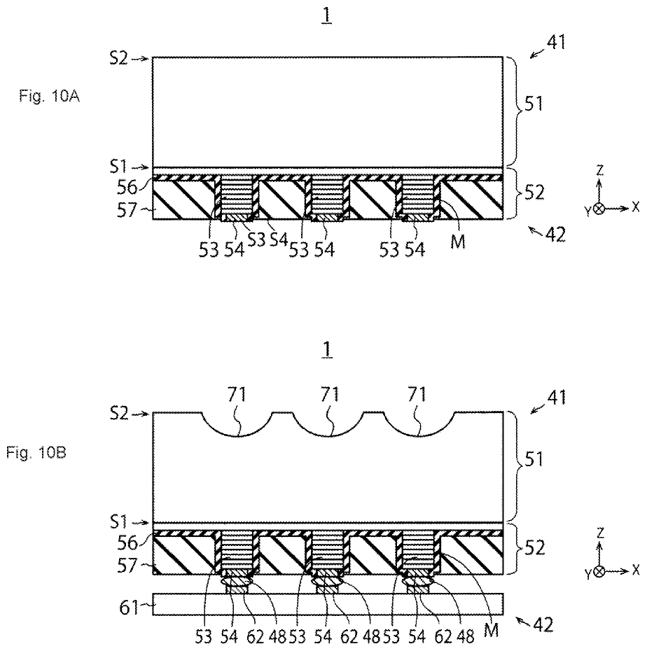

FIG. 10 is a cross-sectional view of the structure of a light-emitting device 1 according to a fourth modification of the first embodiment.

FIG. 10 at A shows the LD chip 41 before being provided on the LDD substrate 42 and illustrates the light-emitting device 1 yet to be completed. Meanwhile, FIG. 10 at B shows the LD chip 41 provided on the LDD substrate 42 and illustrates the light-emitting device 1 in a completed form.

The light-emitting device 1 according to the modification has the same structure as the light-emitting device 1 according to the first embodiment shown in FIG. 4 at A and B but does not include the underfill film 63 (FIG. 10 at B). Therefore, the light-emitting device 1 according to the modification can be easily manufactured since the underfill film 63 does not need to be formed. Meanwhile, the light-emitting device 1 according to the first embodiment shown in FIG. 4 at A and B has the underfill film 63, which is advantageous in that the light-emitting device 1 can have higher reliability.

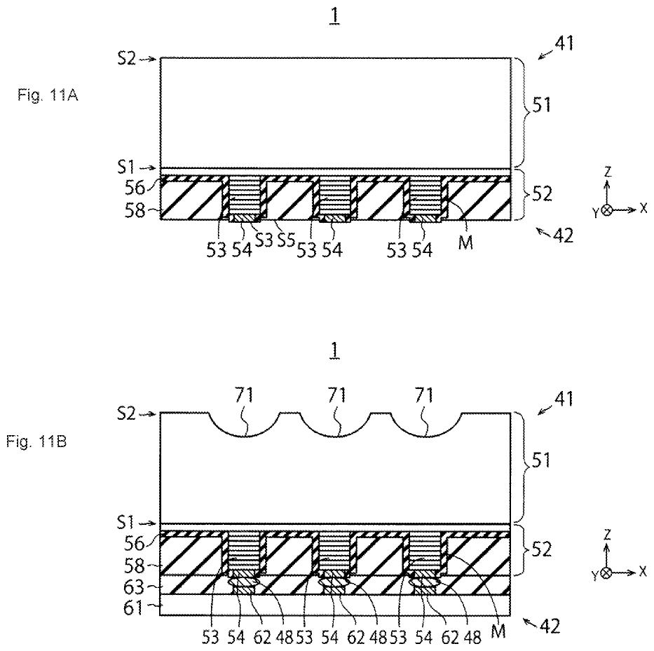

FIG. 11 is a cross-sectional view of the structure of the light-emitting device 1 according to a fifth modification of the first embodiment.

FIG. 11 at A shows the LD chip 41 before being provided on the LDD substrate 42 and illustrates the light-emitting device 1 yet to be completed. Meanwhile, FIG. 11 at B shows the LD chip 41 provided on the LDD substrate 42 and illustrates the light-emitting device 1 in a completed form.

The light-emitting device 1 according to the modification has the same structure as the light-emitting device 1 according to the first embodiment shown in FIG. 4 at A and B, but the organic film 57 is replaced by an inorganic film 58 (FIG. 11 at A). The inorganic film 58 is an example of the film according to the present disclosure.

The insulating film 56 and the inorganic film 58 are formed at the front surface S1 of the substrate 51 to surround the mesa portions M such as the light-emitting elements 53. Specifically, the insulating film 56 is formed on the bottom surface of the laminated film 52 and on the side surfaces of the mesa portions M and functions for example as a passivation film. The inorganic film 58 is formed on the bottom surface of the laminated film 52 and on the side surfaces of the mesa portions M through the insulating film 56.

FIG. 11 at A shows the surface (bottom surface) S3 of the anode electrodes 54 and the surface (bottom surface) S5 of the inorganic film 58. In the LD chip 41 shown in FIG. 11 at A, the front surface S1 of the substrate 51 faces down, and the back surface S2 of the substrate 51 faces up. According to the modification, when the front surface S1 is also the bottom surface of the substrate 51, the lowermost part (lowest part) of the surface S5 of the inorganic film 58 is in a higher position than the surface S3 of the anode electrode 54. Specifically, the surface S5 of the inorganic film 58 in FIG. 11 at A is a flat surface, so that the entire surface S5 of the inorganic film 58 is the lowermost part of the surface S5 of the inorganic film 58, and the entire surface S5 of the inorganic film 58 is in a higher position than the surface S3 of the anode electrode 54. According to the modification, the inorganic film 58 is formed before the LD chip 41 is provided on the LDD substrate 42, and therefore the entire surface S5 of the inorganic film 58 can be set in a higher position than the surface S3 of the anode electrode 54. In this way, for example the anode electrodes 54 can be exposed through the inorganic film 58, and the anode electrodes 54 can be brought into contact with the bumps 48.

The inorganic film 58 is an insulating film according to the modification while the organic film may be either an insulating film or a non-insulating film since the organic film is electrically insulated from the laminated film 52, the light-emitting elements 53, the anode electrodes 54, and the like by the insulating film 56. Therefore, according to the modification, the insulating film 56 and the inorganic film 58 are formed on the front surface S1 of the substrate 51, so that short-circuiting between the elements of the light-emitting device 1 provided on the front surface S1 of the substrate 51 can be suppressed. For example, short-circuiting between the light-emitting elements 53 adjacent to each other or between the anode electrodes 54 thereof. Furthermore, according to the modification, the insulating film 56 and the inorganic film 58 can protect the elements of the light-emitting device 1 provided on the front surface S1 of the substrate 51. For example, the anode electrodes 54 and the cathode electrodes 55 can be restrained from coming off from the mesa portions M.

The inorganic film 58 may be formed with an inorganic material with high passivation performance. Examples of the inorganic film 58 include a silicon oxide film (SiO₂ film), a silicon nitride film (SiN film), and silicon carbide film (SiC film).

The underfill film 63 may be an insulating film. As shown in FIG. 11 at B, the underfill film 63 is formed between the inorganic film 58 and the substrate 61 to surround bumps 48 and the like. As a result, the elements of the light-emitting device 1 that are not protected by the insulating film 56 and inorganic film 58 can be protected by the underfill film 63. For example, this ensures connectivity between the anode electrodes 54, the cathode electrodes 55, and the connection pads 62 and the bumps 48 and connectivity between the bumps 48 adjacent to each other while the insulation between the bumps 48 adjacent to each other can be ensured. The underfill film 63 according to the modification is formed as the underfill film 63 is filled between the inorganic film 58 and the substrate 61 after the LD chip 41 is provided on the LDD substrate 42. The inorganic film 58 according to the modification is not in contact with the substrate 61 but is provided on the substrate 61 through the underfill film 63.

According to the modification, the inorganic film 58 is formed before the LD chip 41 is provided on the LDD substrate 42, so that the filling performance of the film which fills the space surrounding the light-emitting elements 53 can be improved similarly to the case of the organic film 57. According to the modification, the space around the light-emitting elements 53 is filled with the insulating film 56 and the inorganic film 58, and the remaining space between the substrates 51 and 61 is filled with the underfill film 63. In this way, the voids 64 can be reduced and damage to substrate 51 can be reduced. Therefore, according to the modification, the disadvantage of the GaAs substrate can be suppressed while the advantage of the GaAs substrate can be enjoyed.

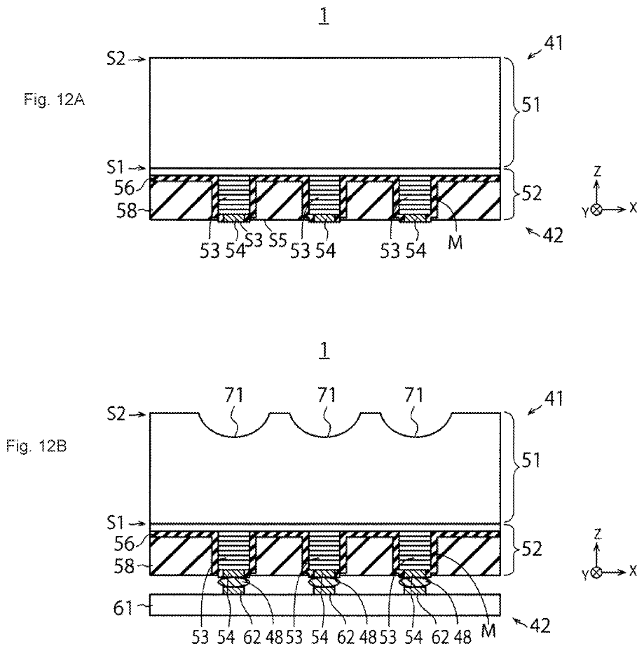

FIG. 12 is a cross-sectional view of the structure of the light-emitting device 1 according to a sixth modification of the first embodiment.

FIG. 12 at A shows the LD chip 41 before being provided on the LDD substrate 42 and illustrates the light-emitting device 1 yet to be completed. Meanwhile, FIG. 12 at B shows the LD chip 41 provided on the LDD substrate 42 and illustrates the light-emitting device 1 in a completed form.

The light-emitting device 1 according to the modification has the same structure as the light-emitting device 1 according to the fifth modification shown in FIG. 11 at A and B but does not include the underfill film 63 (FIG. 12 at B). Therefore, the light-emitting device 1 according to the modification can be easily manufactured since the underfill film 63 does not need to be formed. Meanwhile, the light-emitting device 1 according to the fifth modification shown in FIG. 12 at A and B has the underfill film 63, which is advantageous in that the light-emitting device 1 may have higher reliability.

As in the foregoing, the light-emitting device 1 according to the embodiment includes the organic film 57 (or the inorganic film 58) formed on the front surface S1 of the substrate 51 to surround the light-emitting elements 53. The organic film 57 is formed before the LD chip 41 is provided on the LDD substrate 42. Therefore, when the front surface S1 is the bottom surface of the substrate 51, the lowermost part of the surface S4 of the organic film 57 is in a higher position than the surface S3 of the anode electrode 54. According to the embodiment, the presence of the organic film 57 allows the filling performance of the film which fills the space around the light-emitting elements 53 to be improved.

### Second Embodiment

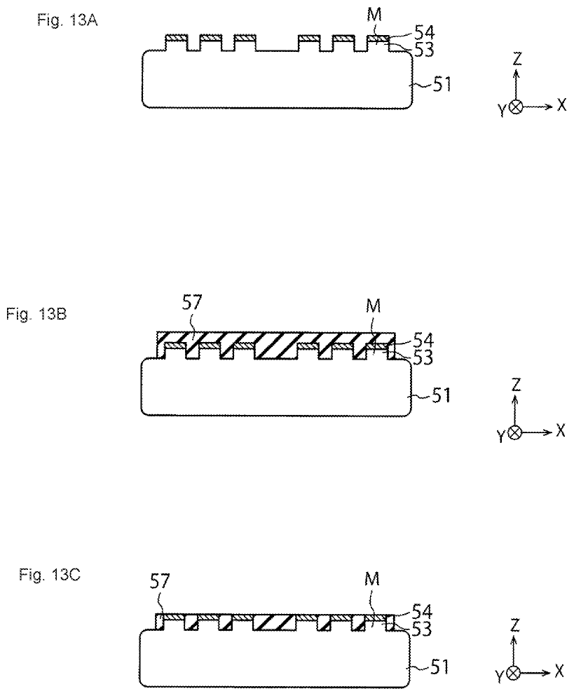

FIGS. 13 to 16 are cross-sectional views for illustrating a method for manufacturing the light-emitting device 1 according to a second embodiment. In the method according to the embodiment, the light-emitting device 1 with the organic film 57 according to the first embodiment is manufactured.

First, a laminated film 52, a plurality of light-emitting elements 53, a plurality of anode electrodes 54, a plurality of cathode electrodes 55, an insulating film 56, and the like are formed on the upper surface of a substrate (wafer) 51 (FIG. 13 at A). However, the laminated film 52, the cathode electrodes 55, and the insulating film 56 are not shown. FIG. 13 at A also shows the above-described plurality of mesa portions M. In FIG. 13 at A, the light-emitting elements 53 and the anode electrode 54 are sequentially formed on the upper surface of the substrate 51. The upper surface of the substrate 51 in FIG. 13 at A is the front surface S1 of the substrate 51. The total thickness of the light-emitting elements 53 and the anode electrodes 54 is for example about 10 μm.

Then, an organic film 57 is formed on the upper surface of the substrate 51 to cover the mesa portions M and the like (FIG. 13 at B). The organic film 57 according to the embodiment may be formed by a coating method.

Then, the upper surface of the organic film 57 is planarized by CMP (FIG. 13 at C). In this way, the organic film 57 is thinned, and the anode electrodes 54 (and the cathode electrodes 55) have their upper surfaces exposed through the organic film 57.

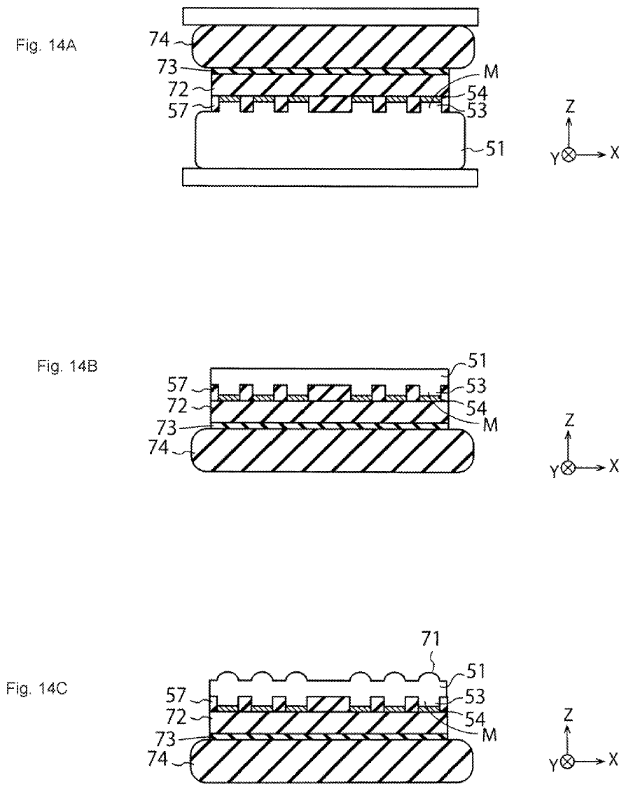

Then, a resin film 72 is formed on the upper surface of the substrate 51 to cover the mesa portions M and the like and the resin film 72 is bonded to a glass substrate (support substrate) 74 with an adhesive 73 (FIG. 14 at A). FIG. 14 at A shows how the substrate 51 and the glass substrate 74 are pressed between two members.

Then, after turning the substrate 51 and the glass substrate 74 upside down, the substrate 51 is thinned (FIG. 14 at B). The upper surface of the substrate 51 in FIG. 14 at B is the back surface S2 of the substrate 51.

Then, a plurality of lenses 71 are formed on the upper surface of the substrate 51 (FIG. 14 at C). According to the embodiment, the upper surface of the substrate 51 is processed to form these lenses 71 as a part of the substrate 51. Each of the lenses 71 according to the embodiment is formed above a corresponding light-emitting element 53, and light emitted from the corresponding light-emitting element 53 is incident on the lens 71. The lenses 71 are convex lenses in FIG. 14 at C but may be other kinds of lenses (for example concave or flat lenses). Note that when the lens 71 is a flat lens, the step in FIG. 14 at C is not necessary.

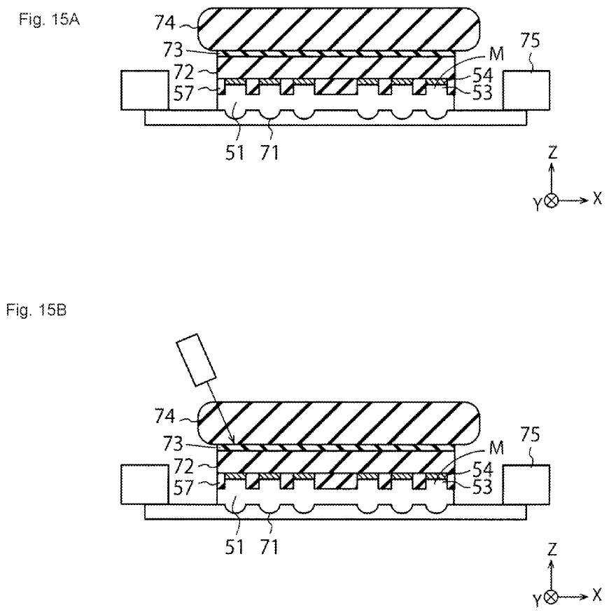

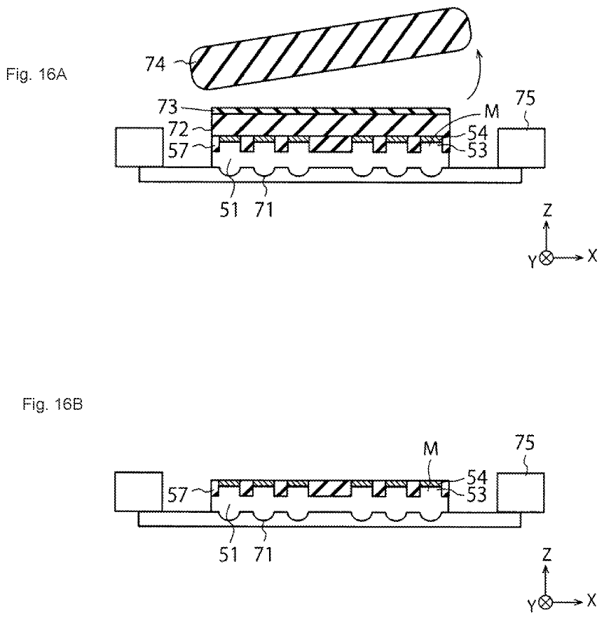

Then, after turning the substrate 51 upside down, the substrate 51 is mounted on the dicing tape of a mounting device 75 (FIG. 15 at A). Then, a laser is used to remove the glass substrate 74 off from the substrate 51 (FIG. 15 at B, FIG. 16 at A). Then, the adhesive 73 and the resin film 72 are removed by cleaning (FIG. 16 at B).

The substrate 51 is then diced into a plurality of individual LD chips 41 at a dicing line. In this way, the LD chip 41 shown in FIG. 7 at A is manufactured. The LD chip 41 is subsequently provided on the LDD substrate 42 through the plurality of bumps 48. In addition, an underfill film 63 is filled between the organic film 57 and the substrate 61 (see FIG. 7 at B). When the underfill film 63 is not necessary, the filling of the underfill film 63 is not carried out. In this way, the light-emitting device 1 shown in FIG. 7 at B is manufactured.

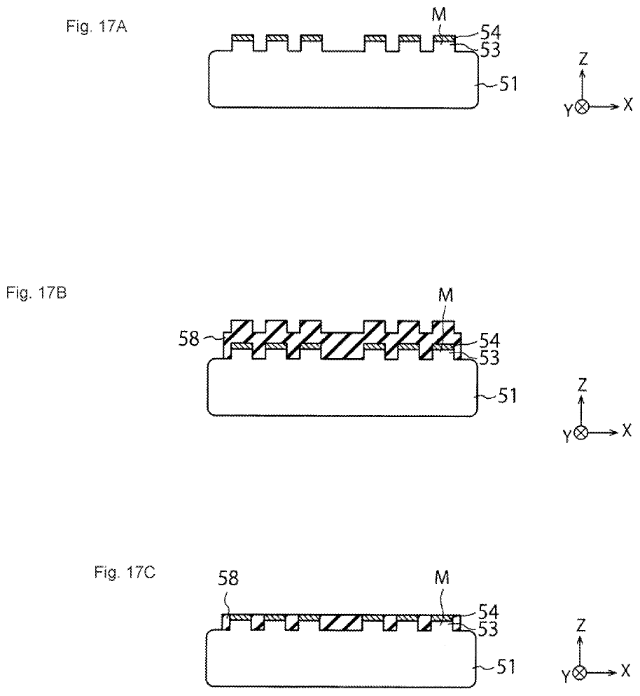

FIG. 17 is a cross-sectional view for illustrating a method for manufacturing the light-emitting device 1 according to a modification of the second embodiment. In the method according to the modification, the light-emitting device 1 according to the first embodiment with the inorganic film 58 is manufactured.

First, a laminated film 52, a plurality of light-emitting elements 53, a plurality of anode electrodes 54, a plurality of cathode electrodes 55, an insulating film 56, and the like are formed on the upper surface of a substrate (wafer) 51 (FIG. 17 at A). However, the laminated film 52, the cathode electrodes 55, and the insulating film 56 are not shown. FIG. 17 at A further shows the above-described plurality of mesa portions M. In FIG. 17 at A, the light-emitting elements 53 and the anode electrodes 54 are formed sequentially on the upper surface of the substrate 51. Note that the upper surface of the substrate 51 in FIG. 17 at A is the front surface S1 of the substrate 51. The total film thickness of the light-emitting elements 53 and the anode electrodes 54 is for example about 10 μm.

Then, an inorganic film 58 is formed on the upper surface of the substrate 51 to cover the mesa portions M and the like (FIG. 17 at B). The inorganic film 58 according to the embodiment is formed for example by CVD (Chemical Vapor Deposition).

Then, the upper surface of the inorganic film 58 is planarized by CMP (FIG. 17 at C). In this way, the inorganic film 58 is thinned and the upper surface of the anode electrode 54 is exposed through the inorganic film 58.

Then, the steps shown in FIG. 14 at A to FIG. 16 at B are performed. However, the organic film 57 in the description of the steps is replaced by the inorganic film 58. Furthermore, the substrate 51 is diced into a plurality of individual LD chips 41 at a dicing line. In this way, the LD chip 41 shown in FIG. 11 at A is manufactured. The LD chip 41 is provided on the LDD substrate 42 through a plurality of bumps 48. In addition, an underfill film 63 is filled between the inorganic film 58 and the substrate 61 (see FIG. 11 at B). When the underfill film 63 is not necessary, the filling of the underfill film 63 is not carried out. In this way, the light-emitting device 1 shown in FIG. 11 at B is manufactured.

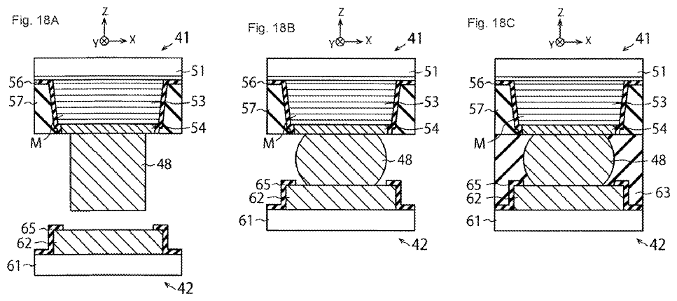

FIG. 18 is a cross-sectional view for illustrating in detail the steps after the steps shown in FIG. 16 at B.

FIG. 18 at A shows the LD chip 41 having the bump 48 provided on the bottom surface of the anode electrodes 54. As shown in FIG. 18 at B, the LD chip 41 is provided on the LDD substrate 42 through the bumps 48. Then, as shown in FIG. 18 at C, an underfill film 63 is filled between the organic film 57 and the substrate 61. In this way, the light-emitting device 1 shown in FIG. 7 at B is manufactured. The method is also applicable when an inorganic film 58 is provided instead of the organic film 57.

Note that FIG. 18 at A to C further shows the insulating film 65 formed on the upper surface of the substrate 61 and on the side surfaces of the connection pads 62. The insulating film 65 may be a silicon oxide film.

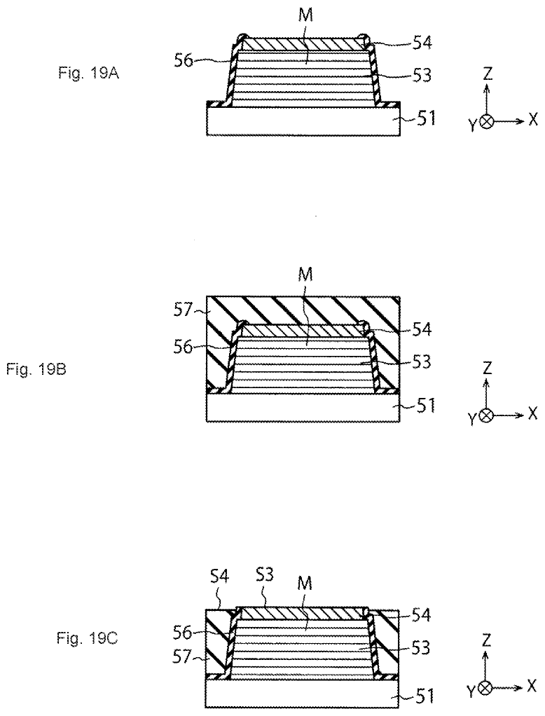

FIG. 19 is a cross-sectional view for illustrating in detail the steps shown in FIG. 13 at A to C.

First, a laminated film 52, a plurality of light-emitting elements 53, a plurality of anode electrodes 54, a plurality of cathode electrodes 55, and the like are formed on the upper surface of a substrate (wafer) 51 (FIG. 19 at A). However, the laminated film 52 and the cathode electrodes 55 are not shown. FIG. 19 at A further shows the above-described plurality of mesa portions M. The upper surface of the substrate 51 in FIG. 19 at A is the front surface S1 of the substrate 51.

Then, an insulating film 56 is formed on the upper surface of the substrate 51 to cover the mesa portions M and the like, and the insulating film 56 is removed from the upper surface of the anode electrode 54 by etching (and the cathode electrode 54) (FIG. 19 at A). In this way, the side surfaces of the mesa portion M are covered with the insulating film 56, and the upper surface of the anode electrode 54 is exposed through the insulating film 56.

Then, an organic film 57 is formed on the upper surface of the substrate 51 to cover the mesa portion M and the like (FIG. 19 at B). In this way, the upper surface of the anode electrode 54 is covered with the organic film 57.

Then, the upper surface of the organic film 57 is planarized by CMP (FIG. 19 at C). In this way, the organic film 57 is thinned, and the upper surface of the anode electrode 54 is exposed through the organic film 57.

FIG. 19 at C shows the surface (upper surface) S3 of the anode electrode 54 and the surface (upper surface) S4 of the organic film 57. Note that the surfaces S3 and S4 in FIG. 4 at A are the bottom surfaces of the anode electrode 54 and the organic film 57, while the surfaces S3 and S4 in FIG. 19 at C are the upper surfaces of the anode electrode 54 and the organic film 57. This is because the substrate 51 shown in FIG. 19 at C has its surface S1 facing up and its back surface S2 facing down.

The organic film 57 according to the embodiment is thinned so that the uppermost part (the highest part) of the surface S4 of the organic film 57 is lower than the surface S3 of the anode electrode 54 (FIG. 19 at C) when the front surface S1 is the upper surface of the substrate 51. Specifically, the surface S4 of the organic film 57 in FIG. 19 at C is a flat surface, so that the entire surface S4 of the organic film 57 is the uppermost part of the surface S4 of the organic film 57, and the entire surface S4 of the organic film 57 is lower than the surface S3 of the anode electrode 54.

The surface S4 is lower than the surface S3 according to the embodiment because the polishing rate for the anode electrode 54 is different from the polishing rate for the organic film 57 during CMP. Specifically, the organic film 57 is more easily polished than the anode electrode 54. Therefore, in FIG. 19 at C, the surface S4 of the organic film 57 is lower than the surface S3 of the anode electrode 54.

Note that the surface S3 of the organic film 57 after CMP does not have to be a flat surface and may be a concave surface. In this case, the uppermost part of the surface S4 of the organic film 57 is in the vicinity of the boundary between the side surface of the organic film 57 and the side surface of the insulating film 56, and the uppermost part is lower than the surface S3 of the anode electrode 56.

According to the embodiment, the insulating film 56 and the organic film 57 may be formed sequentially on the upper surface of the substrate 51 to cover the mesa portion M and the like, and the upper surface of the organic film 57 and the upper surface of the insulating film 56 may be planarized by CMP. In this way, the organic film 57 can be thinned, the insulating film 56 exposed through the organic film 57 can be removed, and the upper surface of the anode electrode 54 can be exposed through the organic film 57 and the insulating film 56.

As in the foregoing, according to the embodiment, the organic film 57 (or the inorganic film 58) is formed on the front surface S1 of the substrate 51 to surround the light-emitting elements 53 before the LD chip 41 is provided on the LDD substrate 42. In this way, when the surface S1 is the upper surface of the substrate 51, the uppermost part of the surface S4 of the organic film 57 is lower than the surface S3 of the anode electrode 54. According to the embodiment, the presence of the organic film 57 improves the filling performance of the film that fills the space around the light-emitting elements 53.

### Third Embodiment

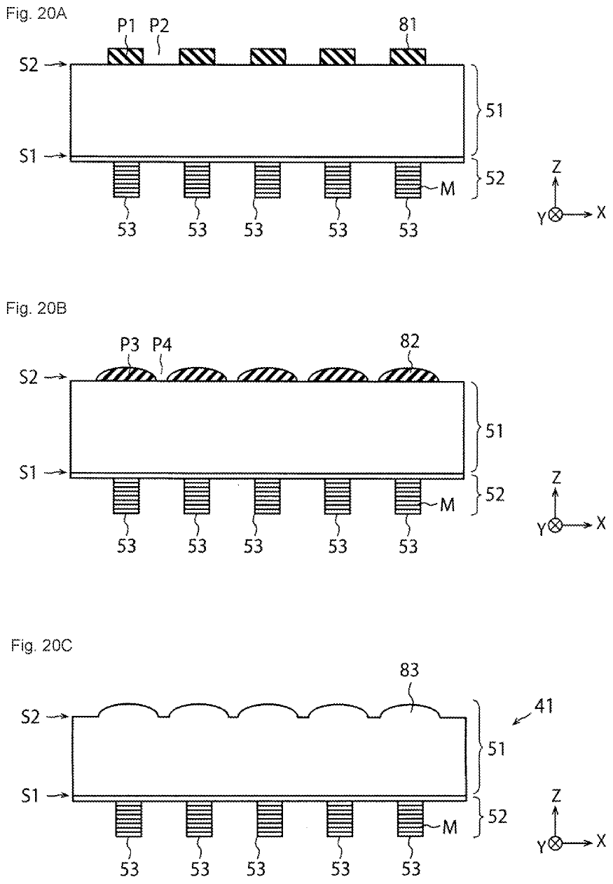

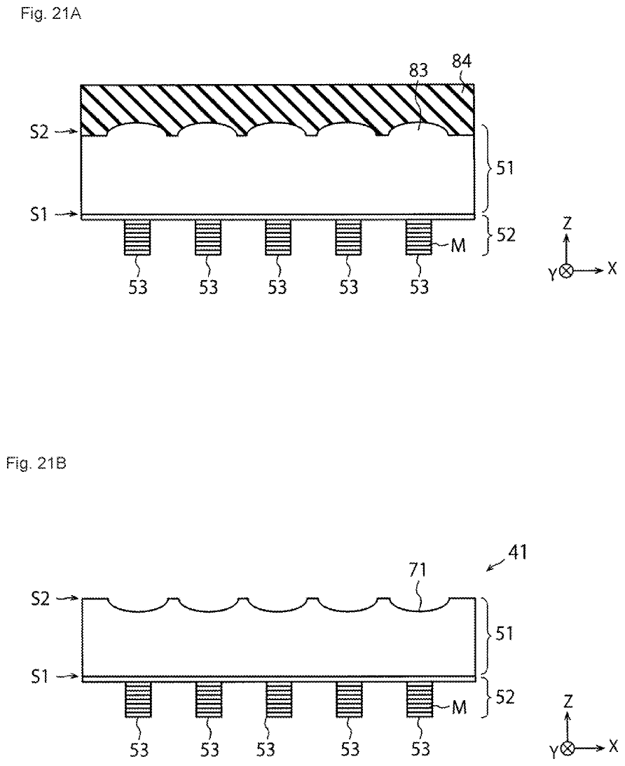

FIGS. 20 and 21 are cross-sectional views for illustrating a method for manufacturing a light-emitting device 1 according to a third embodiment. In this method, the concave lenses (lenses 71) according to the first embodiment are formed.

First, a laminated film 52, light-emitting elements 53, anode electrodes 54, cathode electrodes 55, an insulating film 56, an organic film 57, and the like are formed on the front surface S1 of the substrate 51, then a resist film 81 is formed on the back surface S2 of the substrate 51, and the resist film 81 is patterned by lithography (FIG. 20 at A). As a result, the resist film 81 including a plurality of resist portions P1 and opening portions P2 are formed on the back surface S2 of the substrate 51. The resist portions P1 are formed above the light-emitting elements 53. Note that the anode electrodes 54, the cathode electrodes 55, the insulating films 56, and the organic film 57 are not shown.

Then, the patterned resist film 81 is subjected to reflow baking (FIG. 20 at B). As a result, the resist film 81 is transformed into a resist film 82 containing a plurality of resist portions P3 rounded by surface tension. The resist film 82 includes a plurality of resist portions P3 and opening portions P4.

Then, the resist portions (resist pattern) P3 of the baked resist film 82 are transferred onto the substrate 51 by dry-etching (FIG. 20 at C). As a result, the back surface S2 of the substrate 51 is processed by dry-etching, and a plurality of convex portions 83 in the same shape as the resist portion P3 before dry-etching are formed on the back surface S2 of the substrate 51.

Then, a hard mask layer 84 is formed on the back surface S2 of the substrate 51 to cover these convex portions 83 (FIG. 21 at A). The hard mask layer 84 may be an SOG (Spin On Glass) film.

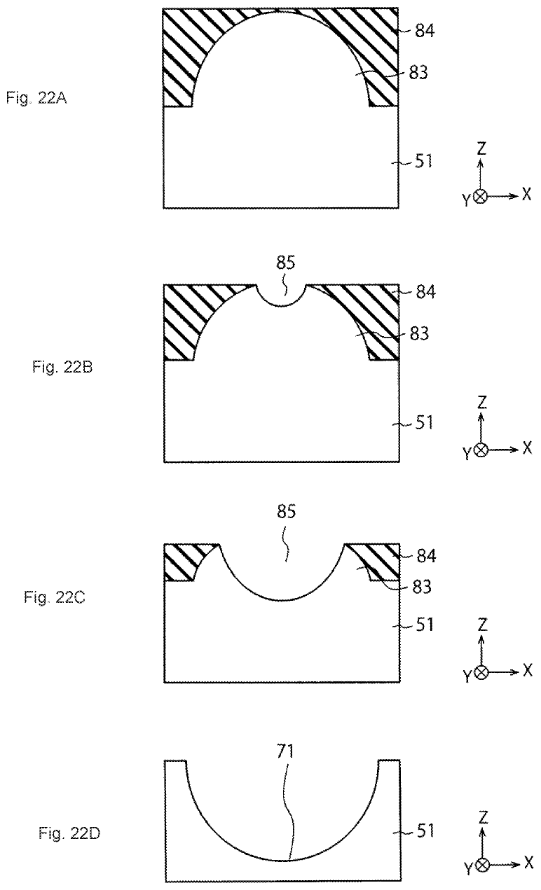

Then, the hard mask layer 84 is gradually removed by dry-etching (FIG. 21 at B). As a result, the convex portions 83 are exposed through the hard mask layer 84 by dry-etching, and the hard mask layer 84 and the convex portions 83 are removed by subsequent dry-etching, and the convex portions 83 change into concave portions, i.e., concave lenses (lenses 71). In this way, a plurality of lenses 71 are formed at the back surface S2 of the substrate 51. Dry-etching is performed, for example, using chlorine gases such as BCl₃ gas and Cl₂ gas (B stands for boron and Cl for chlorine). O₂ (oxygen) gas, N₂ (nitrogen) gas, or Ar (argon) gas may be used along with chlorine gas. The step will be described in detail with reference to FIG. 22.

FIG. 22 is a cross-sectional view for illustrating in detail the step shown in FIG. 21 at B.

FIG. 22 at A shows the convex portion 83 covered with the hard mask layer 84. When the hard mask layer 84 is gradually removed by dry-etching, the convex portion 83 is exposed through the hard mask layer 84 (FIG. 22 at B). In the following dry-etching, the convex portion 83 is etched at a higher etching rate than the hard mask layer 84 since the substrate 51 (GaAs substrate) and the hard mask layer 84 (SOG film) have different etching rates (C in FIG. 22). As a result, a concave portion 85 is formed at the upper end of the convex portion 83, and as the size of the concave portion 85 gradually increases, the convex portion 83 is finally removed, and the concave portion 85 after removal of the convex portion 83 becomes a concave lens (lens 71). The step shown in FIG. 21 at B proceeds in this manner.

Then, according to the embodiment, the steps shown in FIG. 15 at A to FIG. 16 at B and the succeeding steps according to the second embodiment are carried out. In this way, the light-emitting device 1 shown in FIG. 4 at B is manufactured.

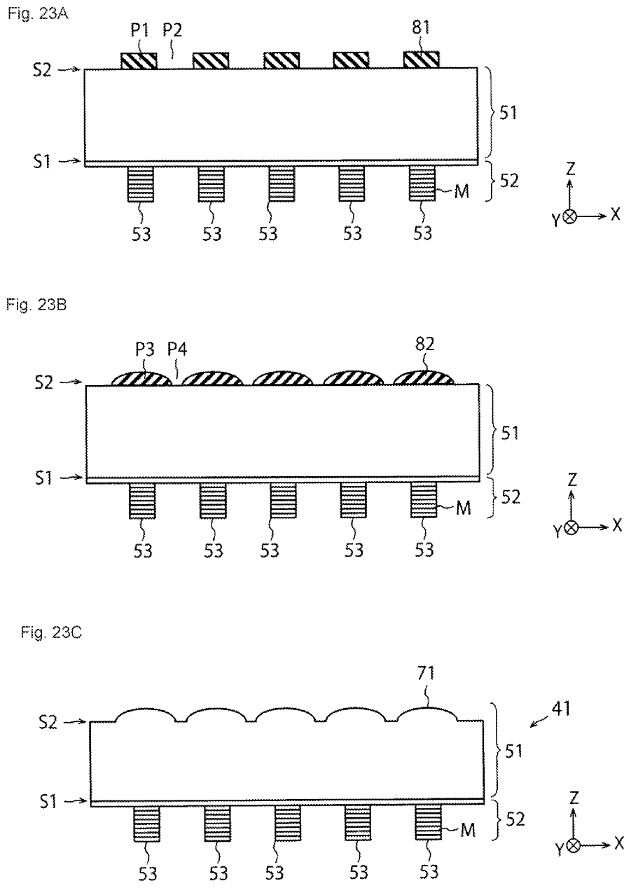

FIG. 23 is a cross-sectional view for illustrating a method for manufacturing a light-emitting device 1 according to a modification of the third embodiment. In the method, the convex lens (lens 71) according to the first embodiment is formed.

First, a laminated film 52, light-emitting elements 53, anode electrodes 54, cathode electrodes 55, an insulating film 56, an organic film 57, and the like are formed on the front surface S1 of the substrate 51, then a resist film 81 is formed on the back surface S2 of the substrate 51, and the resist film 81 is patterned by lithography (FIG. 23 at A). As a result, the resist film 81 including a plurality of resist portions P1 and opening portions P2 is provided on the back surface S2 of the substrate 51. The resist portions P1 are formed above the light-emitting elements 53. Note that the anode electrodes 54, the cathode electrodes 55, the insulating film 56, and the organic film 57 are not shown.

Then, the patterned resist film 81 is subjected to reflow-baking (FIG. 23 at B). As a result, the resist film 81 is transformed into a resist film 82 including a plurality of resist portions P3 rounded by surface tension. The resist film 82 includes the plurality of resist portions P3 and opening portions P4.

Then, the resist portions (resist pattern) P3 of the baked resist film 82 are transferred to the substrate 51 by dry-etching (FIG. 23 at C). As a result, the back surface S2 of the substrate 51 is processed by dry-etching, and a plurality of convex portions, i.e., convex lenses (lenses 71) having the same shape as the resist portions P3 before the dry-etching are formed on the back surface S2 of the substrate 51.

Then, according to the embodiment, the steps in FIG. 15 at A to FIG. 16 at B according to the second embodiment and the succeeding steps are carried out. In this way, the light-emitting device 1 shown in FIG. 7 at B is manufactured.

In this way, the convex lenses can be formed without the step using the hard mask layer 84 and therefore can be more easily formed than concave lenses.

Note that the method illustrated in FIG. 20 at A to FIG. 21 at B can be replaced with other methods. Two examples of such methods will be described in the following.

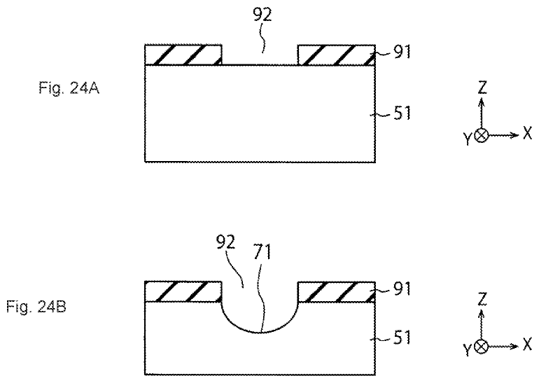

FIG. 24 is a cross-sectional view for illustrating another method 1 different from the method illustrated in FIG. 20 at A to FIG. 21 at B.

First, a hard mask layer 91 is formed on the upper surface (back surface S2) of the substrate 51, and the hard mask layer 91 is provided with opening portions 92 (FIG. 24 at A). The hard mask layer 91 may be a SiO₂ film. In this method, a plurality of opening portions 92 are formed at the hard mask layer 91, while FIG. 24 at A shows one of the opening portions 92.

Then, the upper surface of the hard mask layer 91 is planarized by CMP (Chemical Mechanical Polishing) (FIG. 24 at B). At the time, the upper surface of the substrate 51 exposed in the opening portion 92 is recessed by CMP or a phenomenon called “dishing” occurs. As a result, the upper surface (back surface S2) of the substrate 51 in the opening portion 92 has a recess or a concave lens (lens 71) is formed. More specifically, a plurality of concave lenses (lenses 71) are formed at the back surface S2 of the substrate 51 within the plurality of opening portions 92 of the hard mask layer 91.

In this method, the hard mask layer 91 is then removed, and then the steps in FIG. 15 at A to FIG. 16 at B and the succeeding steps according to the second embodiment are carried out. In this way, the light-emitting device 1 shown in FIG. 4 at B is manufactured.

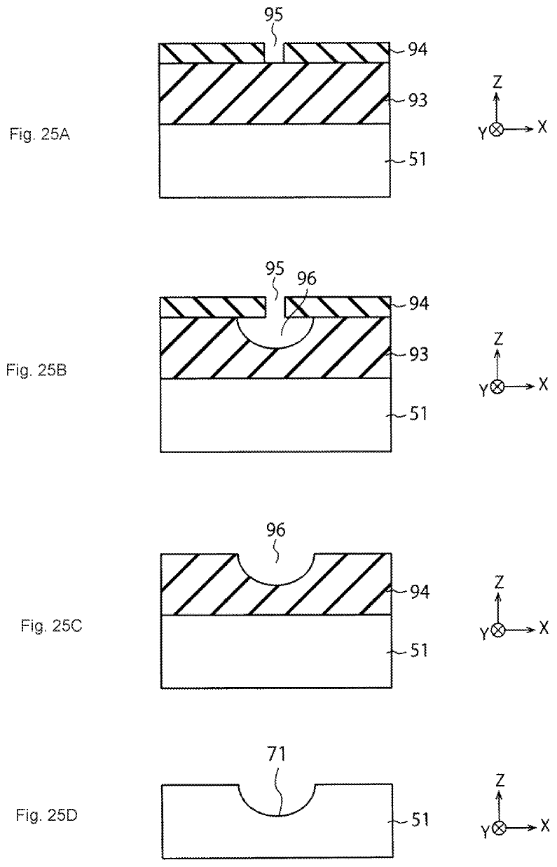

FIG. 25 is a cross-sectional view for illustrating another method 2 different from the method shown in FIG. 20 at A to FIG. 21 at B.

First, a first hard mask layer 93 is formed on the upper surface (back surface S2) of the substrate 51, a second hard mask layer 94 is formed on the first hard mask layer 93, and a small opening portion 95 is formed at the second hard mask layer 94 (FIG. 25 at A). The first hard mask layer 93 may be an organic film such as a carbon film. The second hard mask layer 94 may be a SiO₂ film. In this method, a plurality of opening portions 95 are formed in the second hard mask layer 94, while FIG. 25 at A shows one of the opening portions 95.

Then, the first hard mask layer 93 is processed by isotropic etching using the second hard mask layer 94 as a mask (FIG. 25 at B). As a result, the first hard mask layer 93 exposed in the opening portion 95 is isotropically recessed, and a concave portion 96 is formed in the first hard mask layer 93.

Then, the second hard mask layer 94 is removed (FIG. 25 at C). Then, the concave portion 96 in the first hard mask layer 93 is transferred to the substrate 51 by dry-etching (FIG. 25 at D). As a result, the back surface S2 of the substrate 51 is processed by dry-etching, a concave portion having the same shape as that of the concave portion 96, i.e., a concave lens (lens 71) is formed on the back surface S2 of the substrate 51. More specifically, a plurality of concave lenses (lenses 71) having the same shape as that of the plurality of concave portions 96 are formed on the back surface S2 of the substrate 51.

Then, in this method, the steps in FIG. 15 at A to FIG. 16 at B and the succeeding steps according to the second embodiment are carried out. In this way, the light-emitting device 1 shown in FIG. 4 at B is manufactured.

As in the foregoing, according to the embodiment, concave lenses or convex lenses can be formed as the lenses 71.

### Fourth Embodiment

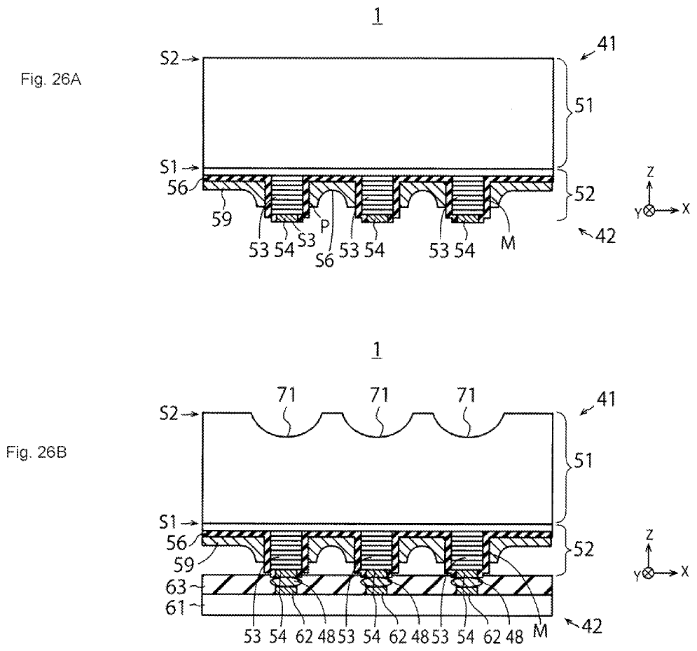

FIG. 26 is a cross-sectional view of the structure of the light-emitting device 1 according to a fourth embodiment.

FIG. 26 at A and B correspond to FIG. 4 at A and B, respectively. Therefore, FIG. 26 at A shows the LD chip 41 before being provided on the LDD substrate 42 and illustrates the light-emitting device 1 yet to be completed. Meanwhile, FIG. 26 at B shows the LD chip 41 provided on the LDD substrate 42 and illustrates the light-emitting device 1 in a completed form.

The light-emitting device 1 according to the embodiment has the same structure as the light-emitting device 1 according to the first embodiment shown in FIG. 4 at A and B but has a metal film 59 instead of the organic film 57 (FIG. 26 at A). The metal film 59 is an example of the film according to the present disclosure.

The insulating film 56 and the metal film 59 are formed on the front surface S1 of the substrate 51 to surround the mesa portions M such as the light-emitting elements 53. Specifically, the insulating film 56 is formed on the bottom surface of the laminated film 52 and on the side surfaces of the mesa portions M, and functions for example as a passivation film. The metal film 59 is formed for example on the bottom surface of the laminated film 52 and on the side surfaces of the mesa portions M through the insulating film 56.

FIG. 26 at A shows the surface (bottom surface) S3 of the anode electrode 54 and the surface (bottom surface) S6 of the metal film 59. In the LD chip 41 shown in FIG. 26 at A, the front surface S1 of the substrate 51 faces down, and the back surface S2 of the substrate 51 faces up. According to the embodiment, when the front surface S1 is the bottom surface of the substrate 51, the lowermost part (the lowest part) P of the surface S6 of the metal film 59 is provided in a higher position than the surface S3 of the anode electrode 54. Specifically, since the surface S6 of the metal film 59 in FIG. 26 at A is a concave surface, the lowermost part P of the surface of S6 of the metal film 59 is positioned in the vicinity of the boundary between the side surface of the metal film 59 and the side surface of the insulating film 56, and the lowermost part P is provided in a higher position than the surface S3 of the anode electrode 56. According to the embodiment, since the metal film 59 is formed before the LD chip 41 is provided on the LDD substrate 42, the lowermost part P of the surface S6 of the metal film 59 can be set higher than the surface S3 of the anode electrode 54. In this way, for example the anode electrodes 54 can be exposed through the metal film 59, so that the anode electrodes 54 can be brought into contact with the bumps 48.

The metal film 59 is a conductive film according to the embodiment while the metal film may be either a conductive film or an insulating film since the metal film is electrically insulated from the laminated film 52, the light-emitting elements 53, the anode electrodes 54, and the like by the insulating film 56. Therefore, according to the embodiment, the metal film 59 is formed on the front surface S1 of the substrate 51 through the insulating film 56, so that short-circuiting between the elements of the light-emitting device 1 provided on the front surface S1 of the substrate 51 can be reduced by the insulating film 56. For example, the insulating film 56 can reduce short-circuiting between adjacent light-emitting elements 53 or the anode electrodes 54 thereof. Furthermore, according to the embodiment, the elements of the light-emitting device 1 provided on the surface S1 of the substrate 51 to be protected by the insulating film 56 and the metal film 59. For example, the anode electrodes 54 or the cathode electrode 55 can be restrained from coming off from the mesa portions M.

The metal film 59 is for example made of a metallic material with good thermal conductivity and has higher thermal conductivity than that of the substrate 51 according to the embodiment. Examples of the metal film 59 include a Ti (titanium) film, a Cu (copper) film, an Al (aluminum) film, a W (tungsten) film, a Au (gold) film, a Pt (platinum) film, and a Ag (silver) film.

The underfill film 63 may be an insulating film. As shown in FIG. 26 at B, the underfill film 63 is formed between the metal film 59 and the substrate 61 to surround the bumps 48 and the like. In this way, the elements of the light-emitting device 1 that are not protected by the insulating film 56 or the metal film 59 can be protected by the underfill film 63. For example, this ensures the connectivity between the anode electrodes 54, the cathode electrodes 55, and the connection pads 62 and the bumps 48 and the insulation between the bumps 48 adjacent to each other. The underfill film 63 according to the embodiment is formed as the underfill film 63 is filled between the metal film 59 and the substrate 61 after the LD chip 41 is provided on the LDD substrate 42. The metal film 59 according to the embodiment is not in contact with the substrate 61 or the underfill film 63 but is provided above the substrate 61 and the underfill film 63 through an air gap. The lenses 71 according to the embodiment are formed after the metal film 59 is formed similarly to the case of the organic film 57.

According to this embodiment, the metal film 59 is formed before the LD chip 41 is provided on the LDD substrate 42, so that the filling performance of the film which fills the space around the light-emitting elements 53 can be improved similarly to the case of the organic film 57. According to the embodiment, the space around the light-emitting elements 53 is filled with the insulating film 56 and the metal film 59, and the space between the substrates 51 and 61 is further filled with the underfill film 63. This allows the voids 64 or damage to the substrate 51 to be reduced. Therefore, according to the embodiment, the disadvantage of the GaAs substrate can be suppressed while the advantage of the GaAs substrate can be enjoyed.

Now, the metal film 59 according to the embodiment will be described in more detail.

In the light-emitting device 1 according to the embodiment, heat is generated from the light-emitting elements 53 and the like. The heat generated from the light-emitting elements 53 and the like may be radiated to the heat dissipation substrate 44 for example through the LDD substrate 42 (see FIG. 2 at B). This allows the heat to escape from the light-emitting elements 53 and the like.

However, such heat dissipation alone may not be sufficient. Insufficient heat dissipation in the light-emitting device 1 may cause saturation of the optical output from the light-emitting elements 53, fluctuations in the wavelength of the optical output from the light-emitting elements 53, and thermal crosstalk in the light-emitting device 1. Specifically, it is desirable to promote heat dissipation in the vicinity of the light-emitting elements 53.

Therefore, according to the embodiment, a metal film 59 is provided on the front surface S1 of the substrate 51. This allows heat generated from the light-emitting elements 53 and the like to escape also to the metal film 59. As described above, the metal film 59 is for example made of a metallic material with good thermal conductivity and has higher thermal conductivity than the substrate 51 according to the embodiment. This makes it easier for heat to escape to the metal film 59 than the case where there is no metal film 59 and heat escapes to the substrate 51.

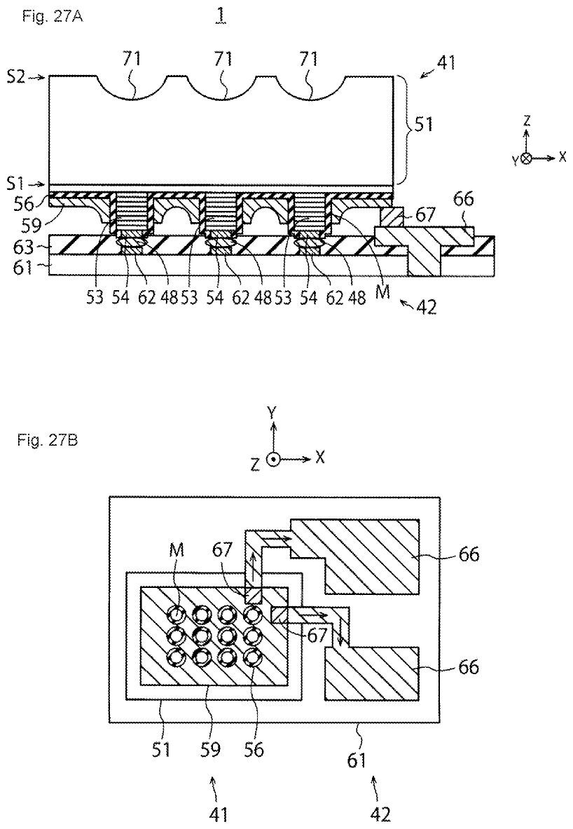

FIG. 27 is a cross-sectional view of the structure of a light-emitting device 1 according to a first modification of the fourth embodiment (FIG. 27 at A) and a plan view thereof (FIG. 27 at B).

FIG. 27 at A shows a longitudinal section which corresponds to FIG. 26 at B. In addition to the elements shown in FIG. 26 at B, the light-emitting device 1 according to the modification has one or more heat sinks 66, and a conductive adhesive 67 provided on the upper surface of the heat sinks 66 (FIG. 27 at A). FIG. 27 at B shows the positional relation of the heat sinks 66 and the like to the substrate 51 and the like. FIG. 27 at B shows, as an example, two heat sinks 66 provided in the light-emitting device 1.

FIG. 27 at A shows a longitudinal section of one of these heat sinks 66. The heat sink 66 shown in FIG. 27 at A is provided in the substrate 61 and the underfill film 63 and is in contact with the heat dissipation substrate 44 which is not shown (see FIG. 2 at B). The conductive adhesive 67 shown in FIG. 27 at A is provided between the heat sink 66 and the metal film 59 and adheres the heat sink 66 to the metal plate 59. Therefore, according to the modification, heat transferred from the light-emitting element 53 and the like to the metal film 59 is allowed to escape to the heat dissipation substrate 44 through the conductive adhesive 67 and the heat sink 66. This applies to the other heat sink 66 of the light-emitting device 1.

FIG. 27 at B shows the two heat sinks 66 arranged near the substrate 51. Each of the heat sinks 66 is connected to the metal film 59 through the conductive adhesive 67. This allows heat to escape from the metal film 59 to each of the heat sinks 66 as indicated by the arrows in FIG. 27 at B.

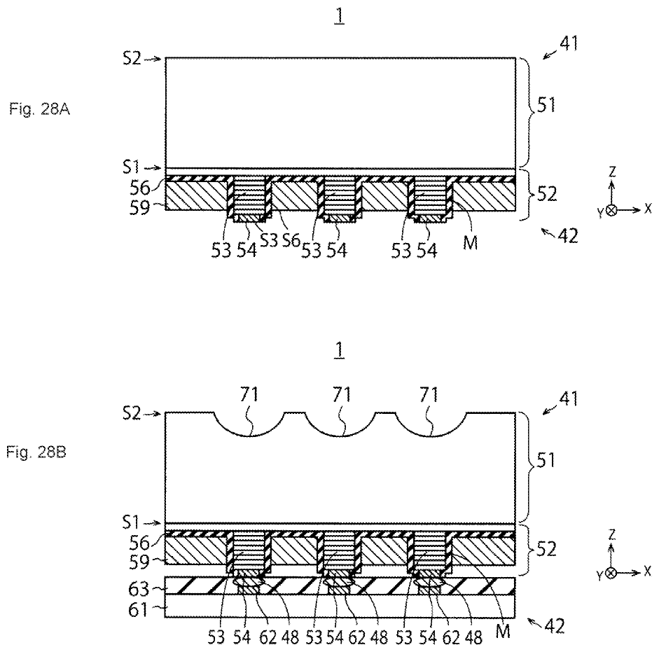

FIG. 28 is a cross-sectional view of the structure of a light-emitting device 1 according to a second modification of the fourth embodiment.

FIG. 28 at A shows the LD chip 41 before being provided on the LDD substrate 42 and illustrates the light-emitting device 1 yet to be completed. Meanwhile, FIG. 28 at B shows the LD chip 41 provided on the LDD substrate 42 and illustrates the light-emitting device 1 in a completed form.

According to the modification, when the front surface S1 is the bottom surface of the substrate 51, the lowermost part (the lowest part) of the surface S6 of the metal film 59 is provided in a higher position than the surface S3 of the anode electrode 54 (FIG. 28 at A). However, the surface S6 of the metal film 59 in FIG. 28 at A is not concave but flat. Therefore, the entire surface S6 of the metal film 59 is the lowermost part of the entire surface S6 of the metal film 59 and provided in a higher position than the surface S3 of the anode electrode 54. According to the modification, the metal film 59 is formed before the LD chip 41 is provided on the LDD substrate 42, and therefore the entire surface S6 of the metal film 59 can be set higher than the surface S3 of the anode electrode 54. In this way, for example the anode electrodes 54 can be exposed through the metal film 59, and the anode electrodes 54 can be brought into contact with the bumps 48.

Here, the fourth embodiment shown in FIG. 26 at A and B and the modification shown in FIG. 28 at A and B will be compared.

According to the fourth embodiment, the surface S6 of the metal film 59 is concave, so that there is a large air gap between the metal film 59 and the underfill film 63. According to the modification, the volume of this air gap can be reduced and the light-emitting elements 53 can be almost entirely embedded in the metal film 59. The structure has for example the advantage of facilitating heat dissipation into the metal film 59 and protecting the light-emitting elements 53 more effectively. The metal film 59 according to the modification is made for example from Ag (silver) paste.

Meanwhile, the fourth embodiment has the advantage that when the metal film 59 has a reduced volume, the metal film 59 can be formed more easily. This is effective for example when the metal film 59 is made of a metallic material which is difficult to be filled into the region between the light-emitting elements 53. The metal film 59 according to the fourth embodiment may be formed by a plating method.

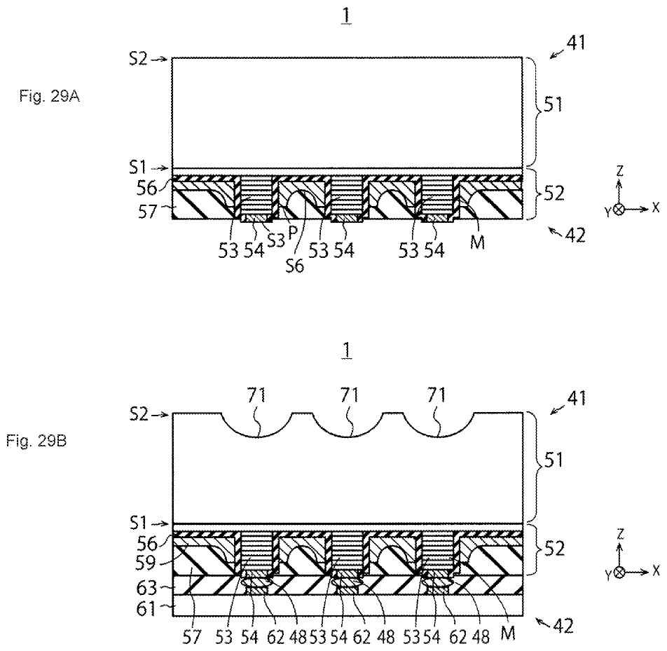

FIG. 29 is a cross-sectional view of the structure of the light-emitting device 1 according to a third modification of the fourth embodiment.

The light-emitting device 1 according to the modification has the same structure as that of the light-emitting device 1 according to the fourth embodiment shown in FIG. 26 at A and B and includes an organic film 57 in addition to the metal film 59 (FIG. 29 at A). According to the modification, an insulating film 56, a metal film 59, and an organic film 57 are formed on the front surface S1 of the substrate 51 to surround mesa portions M such as light-emitting elements 53. Specifically, the insulating film 56, the metal film 59, and the organic film 57 are sequentially formed on the bottom surface of the laminated film 52 and the side surfaces of the mesa portions M. The insulating film 56, the metal film 59, and the organic film 57 according to the modification are formed before the LD chip 41 is provided on the LDD substrate 42. According to the modification, the elements of the light-emitting device 1 on the front surface S1 of the substrate 51 can be protected by the insulating film 56, the metal film 59, and the organic film 57.

As shown in FIG. 29 at B, the underfill film 63 according to the modification is formed between the organic film 57 and the substrate 61 to surround the bumps 48 and the like. The underfill film 63 according to the modification is formed as the underfill film 63 is filled between the organic film 57 and the substrate 61 after the LD chip 41 is provided on the LDD substrate 42. The organic film 57 according to the modification is not in contact with the substrate 61 but is provided on the substrate 61 through the underfill film 63.

As in the foregoing, the light-emitting device 1 according to the embodiment includes the metal film 59 formed on the front surface S1 of the substrate 51 to surround the light-emitting elements 53. The metal film 59 is formed before the LD chip 41 is provided on the LDD substrate 42. Therefore, when the front surface S1 is the bottom surface of the substrate 51, the lowermost part of the surface S6 of the metal film 59 is provided in a higher position than the surface S3 of the anode electrode 54. According to the embodiment, the presence of the metal film 59 improves the filling performance of the film that fills the space around the light-emitting elements 53 and allows heat to escape to the metal film 59 from the light-emitting elements 53 and the like.

### Fifth Embodiment

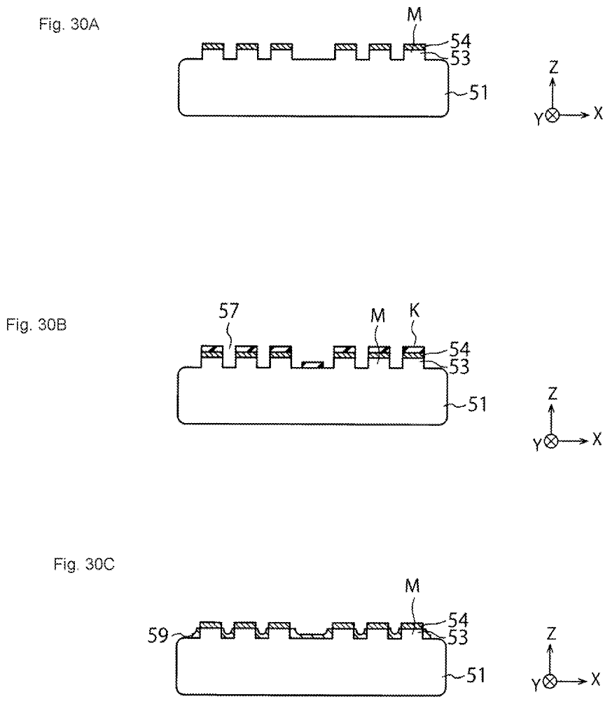

FIGS. 30 to 33 are cross-sectional views for illustrating a method for manufacturing a light-emitting device 1 according to a fifth embodiment. In the method according to the embodiment, the light-emitting device 1 according to the fourth embodiment with the metal film 59 is manufactured, and after the metal film 59 is formed, lenses 71 are formed.

First, a laminated film 52, a plurality of light-emitting elements 53, a plurality of anode electrodes 54, a plurality of cathode electrodes 55, an insulating film 56 and the like are formed on the upper surface of a substrate (wafer) 51 (FIG. 30 at A). However, the laminated film 52, the cathode electrodes 55, and the insulating film 56 are not shown. FIG. 30 at A further shows the above-described plurality of the mesa portions M. In FIG. 30 at A, the light-emitting elements 53 and the anode electrodes 54 are sequentially formed on the upper surface of the substrate 51. The upper surface of the substrate 51 in FIG. 30 at A is the front surface S1 of the substrate 51. The total thickness of the light-emitting elements 53 and the anode electrodes 54 is for example about 10 μm.

Then, a mask film K is formed for example on the upper surfaces of the mesa portions M (FIG. 30 at B). The mask film K may be a resist film.

Then, the metal film 59 is formed on the upper surface of the substrate 51 (FIG. 30 at C). Since the upper surfaces of the mesa portions M are covered with the mask film K, the metal film 59 is formed in the gap between the mesa portions M. In this way, the metal film 59 is formed to surround the mesa portions M. The metal film 59 according to the embodiment is formed for example by sputtering, vapor deposition, plating, or CVD. FIG. 30 at C shows the state in which the mask film K has been removed after the formation of the metal film 59.

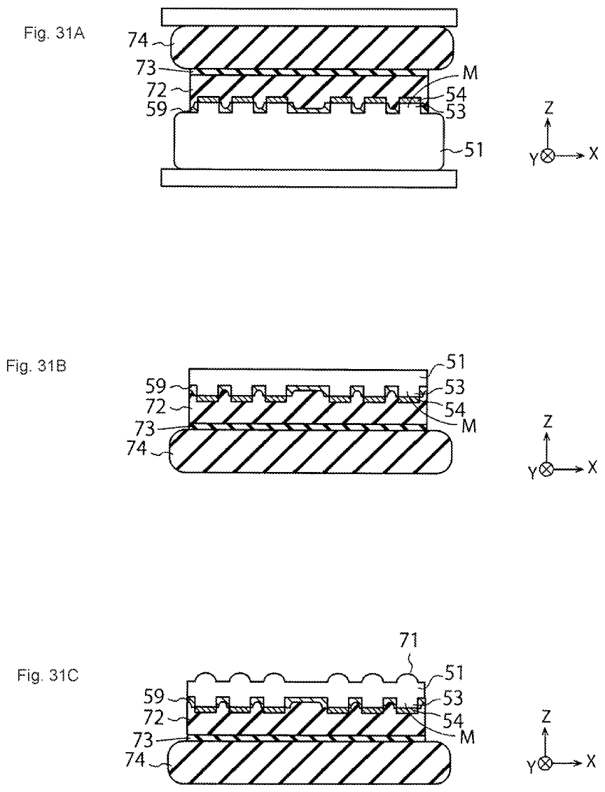

Then, a resin film 72 is formed on the upper surface of the substrate 51 to cover the mesa portions M and the like, and the resin film 72 is bonded with a glass substrate (support substrate) 74 by an adhesive 73 (FIG. 31 at A). FIG. 31 at A shows how the substrate 51 and the glass substrate 74 are pressed between two members.

Then, after turning the substrate 51 and the glass substrate 74 upside down, the substrate 51 is thinned (FIG. 31 at B). The upper surface of the substrate 51 in FIG. 31 at B is the back surface S2 of the substrate 51.

Then, a plurality of lenses 71 are formed on the upper surface of the substrate 51 (FIG. 31 at C). According to the embodiment, the lenses 71 are formed as a part of the substrate 51 by processing the upper surface of the substrate 51. Each of the lenses 71 according to the embodiment is formed above a corresponding light-emitting element 53, and light emitted from the corresponding light-emitting element 53 is incident on the lens. The lenses 71 are convex lenses in FIG. 31 at C but may be any other kind of lenses (for example, concave or flat lenses). When the lens 71 is a flat lens, the step in FIG. 31 at C is not necessary.

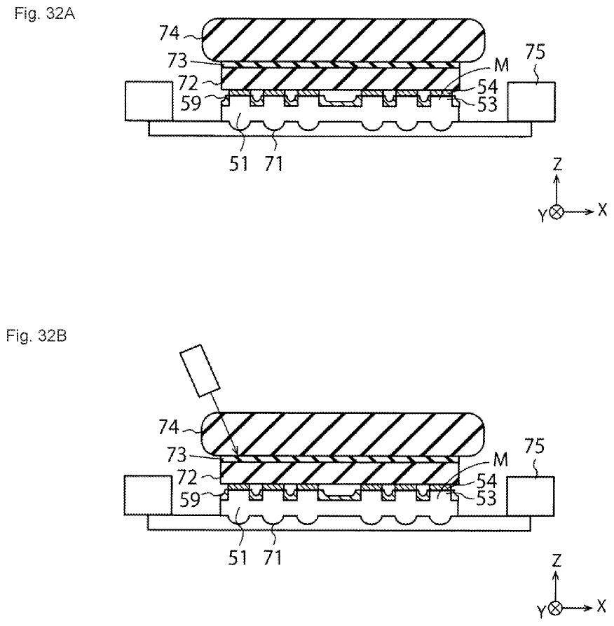

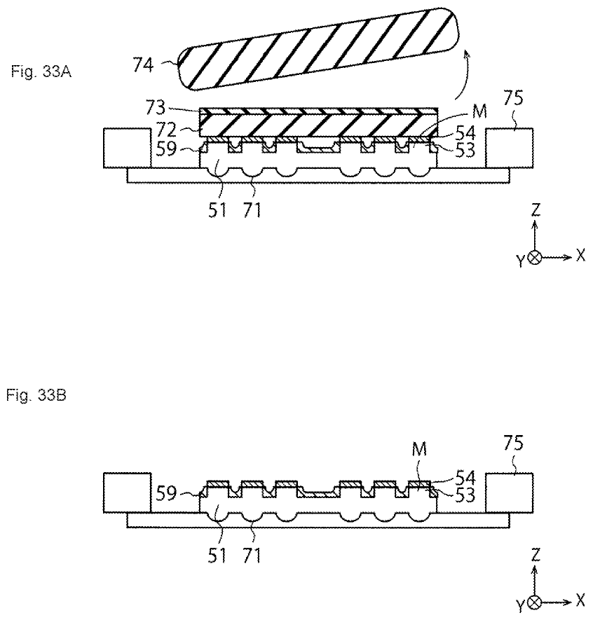

Then, after turning the substrate 51 upside down, the substrate 51 is mounted on the dicing tape of the mounting device 75 (FIG. 32 at A). Then, a laser is used to remove the glass substrate 74 off from the substrate 51 (FIG. 32 at B, FIG. 33 at A). Then, the adhesive 73 and the resin film 72 are removed by cleaning (FIG. 33 at B).

Thereafter, the substrate 51 is diced into a plurality of individual LD chips 41 at a dicing line. In this way, the LD chip 41 according to the fourth embodiment is manufactured. The LD chips 41 are subsequently provided on the LDD substrate 42 through a plurality of bumps 48. In addition, an underfill film 63 is filled between the metal film 59 and the substrate 61 (see FIG. 26 at B). When the underfill film 63 is not necessary, the filling of the underfill film 63 is not carried out. In this way, the light-emitting device 1 according to the fourth embodiment is manufactured.

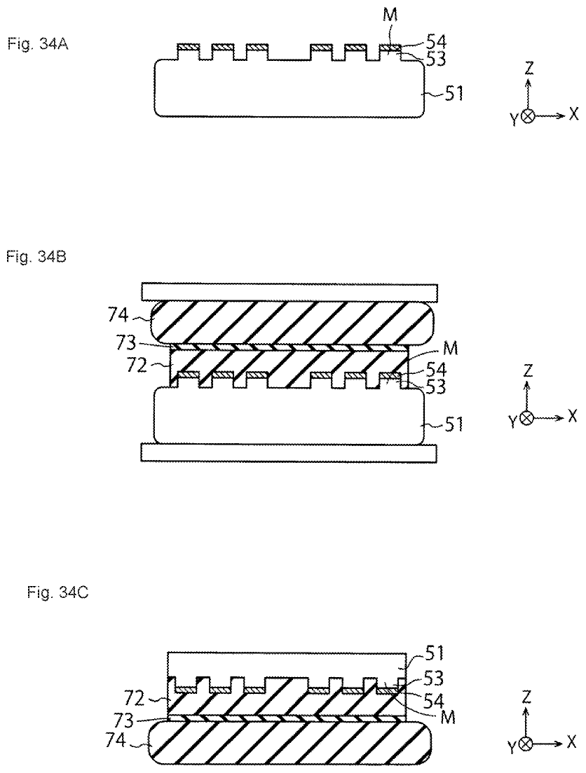

FIGS. 34 to 37 are cross-sectional views for illustrating a method for manufacturing a light-emitting device 1 according to a modification of the fifth embodiment. In the method according to the modification, the light-emitting device 1 with a metal film 59 according to the fourth embodiment is manufactured, and lenses 71 are formed before the metal film 59 is formed.

First, a laminated film 52, a plurality of light-emitting elements 53, a plurality of anode electrodes 54, a plurality of cathode electrodes 55, an insulating film 56, and the like are formed on the upper surface of a substrate (wafer) 51 (FIG. 34 at A). However, the laminated film 52, the cathode electrodes 55, and the insulating film 56 are not shown. FIG. 34 at A further shows the above-described plurality of mesa portions M. The upper surface of the substrate 51 in FIG. 34 at A is the front surface S1 of the substrate 51.

Then, a resin film 72 is formed on the upper surface of the substrate 51 to cover the mesa portions M and the like and the resin film 72 is bonded with a glass substrate (support substrate) 74 with an adhesive 73 (FIG. 34 at B). FIG. 34 at B shows how the substrate 51 and the glass substrate 74 are pressed between two members.

Then, after turning the substrate 51 and the glass substrate 74 upside down, the substrate 51 is thinned (FIG. 34 at C). The upper surface of the substrate 51 in FIG. 34 at C is the back surface S2 of the substrate 51.

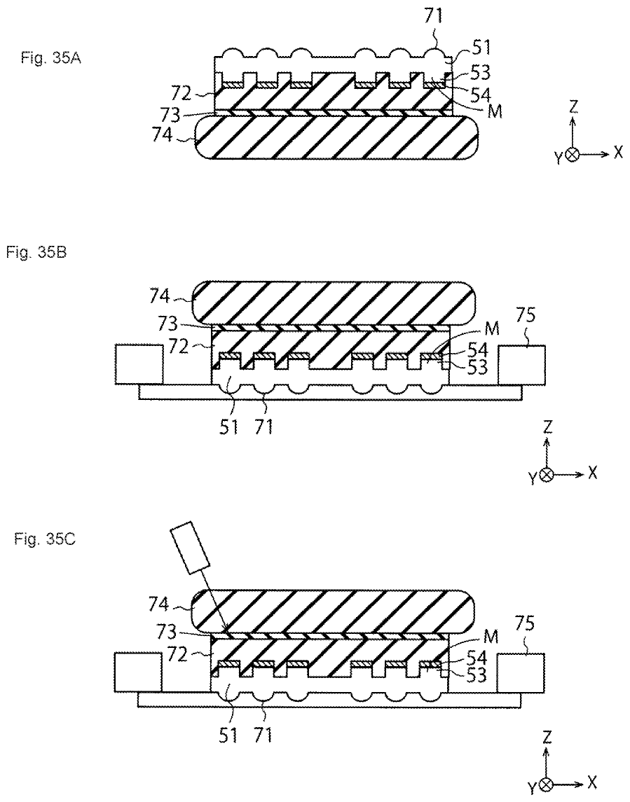

Then, a plurality of lenses 71 are formed on the upper surface of the substrate 51 (FIG. 35 at A). According to the modification, the lenses 71 are formed as a part of the substrate 51 by processing the upper surface of the substrate 51. The lenses 71 are convex lenses in FIG. 35 at A but may be any other kinds of lenses (for example, concave or flat lenses). When the lenses 71 are flat lenses, the step shown in FIG. 35 at A is not necessary.

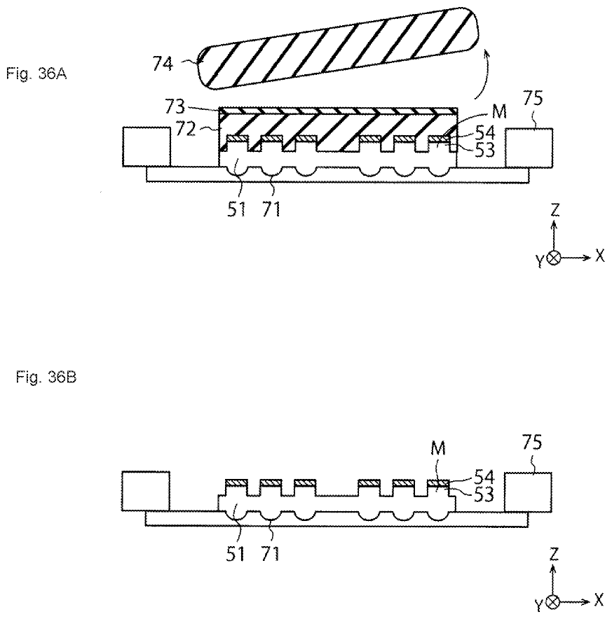

Then, after turning the substrate 51 upside down, the substrate 51 is mounted on the dicing tape of the mounting device 75 (FIG. 35 at B). Then, a laser is used to remove the glass substrate 74 from the substrate 51 (FIG. 35 at C, FIG. 36 at A). Then, the adhesive 73 and the resin film 72 are removed by cleaning (FIG. 36 at B).

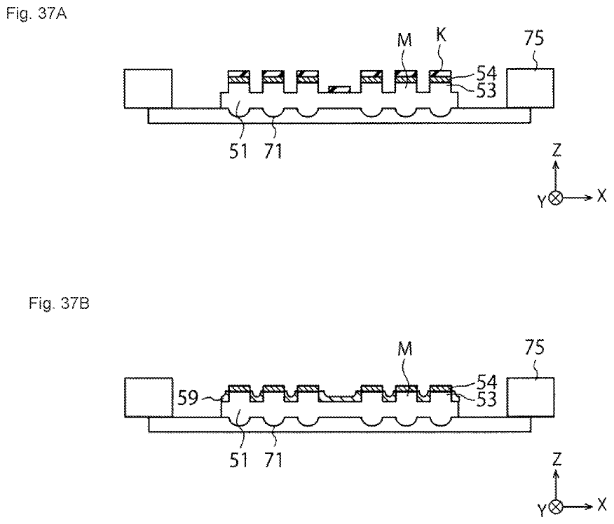

Then, a mask film K is formed for example on the upper surface of the mesa portions M (FIG. 37 at A). The mask film K may be a resist film.

Then, a metal film 59 is formed on the upper surface of the substrate 51 (FIG. 37 at B). Since the upper surfaces of the mesa portions M are covered with the mask film K, the metal film 59 is formed in the gap between the mesa portions M. In this way, the metal film 59 is formed to surround the mesa portions M. Note that FIG. 37 at B shows the state in which the mask film K has been removed after the formation of the metal film 59.

Thereafter, the substrate 51 is diced into a plurality of individual LD chips 41 at a dicing line. In this way, the LD chips 41 according to the fourth embodiment are manufactured. The LD chip 41 is subsequently provided on the LDD substrate 42 through a plurality of bumps 48. In addition, an underfill film 63 is filled between the metal film 59 and the substrate 61 (see FIG. 26 at B). When the underfill film 63 is not necessary, the filling of the underfill film 63 is not carried out. In this way, the light-emitting device 1 according to the fourth embodiment is manufactured.

Note that the lenses 71 according to the embodiment can be formed for example by the described method according to the third embodiment. The described method according to the third embodiment may be applied to the lenses 71 formed before or after the formation of the metal film 59.

The content according to the second embodiment described with reference to FIGS. 18 and 19 is also applied to the fifth embodiment. Note however that when the described content is applied to the fifth embodiment, the organic film 57 is replaced with the metal film 59.

As in the foregoing, according to the embodiment, the metal film 59 is formed on the front surface S1 of the substrate 51 to surround the light-emitting elements 53 before the LD chip 41 is provided on the LDD substrate 42. In this way, when the front surface S1 is the upper surface of the substrate 51, the uppermost part of the surface S6 of the metal film 59 is lower than the surface S3 of the anode electrode 54. According to the embodiment, the presence of the metal film 59 provided in this manner improves the filling performance of the film that fills the space around the light-emitting elements 53 and allows heat to escape from the light-emitting elements 53 and the like into the metal film 59.

Although the light-emitting devices 1 according to the first to fifth embodiments are each used as a light source for a distance measuring device, the devices may be used in other ways. For example, the light-emitting devices 1 according to the embodiments may be used as light sources for optical devices such as printers or may be used as lighting devices.

The embodiments of the present disclosure have been described but the embodiments may be carried out with various changes without departing from the gist of the present disclosure. For example, two or more embodiments may be carried out in combination.

Note that the present disclosure may be configured as follows.

(1) A light-emitting device comprising:

a substrate;

a plurality of light-emitting elements and a plurality of electrodes sequentially provided on a first surface of the substrate; and

a film provided on the first surface of the substrate to surround the light-emitting elements, wherein

when the first surface is a bottom surface of the substrate, the lowermost part of a bottom surface of the film is provided in a higher position than a bottom surface of the electrode.

(2) The light-emitting device according to (1), further comprising a plurality of lenses which are provided on a second surface of the substrate as a part of the substrate and on which light emitted from the light-emitting elements is incident.

(3) A method for manufacturing the light-emitting device according to (2), wherein the lenses include at least one of a concave lens, a convex lens, and a flat lens.

(4) The light-emitting device according to (1), wherein the substrate is a semiconductor substrate including gallium (Ga) and arsenic (As).

(5) The light-emitting device according to (1), wherein the film surrounds the light-emitting elements through an insulating film.

(6) The light-emitting device according to (1), wherein the film is an insulating film.

(7) The light-emitting device according to (1), wherein the film is an organic film or an inorganic film.

(8) The light-emitting device according to (1), wherein the film is a metal film.

(9) The light-emitting device according to (1), wherein the film has a thermal conductivity higher than that of the substrate.

(10) The light-emitting device according to (1), wherein the substrate is provided on a second substrate, and the film is not in contact with the second substrate.

(11) The light-emitting device according to (10), wherein the second substrate is a semiconductor substrate including silicon (Si).

(12) The light-emitting device according to (10), further comprising a fill film provided between the film and the second substrate.

(13) The light-emitting device according to (10), further comprising a heat sink and a conductive adhesive provided between the heat sink and the film.

(14) A method for manufacturing a light-emitting device comprising:

sequentially forming a plurality of light-emitting elements and a plurality of electrodes on a first surface of a substrate; and

forming a film on the first surface of the substrate to surround the light-emitting elements, wherein

when the first surface is an upper surface of the substrate, the uppermost part of an upper surface of the film is formed to be lower than an upper surface of the electrode.

(15) The method for manufacturing a light-emitting device according to (14), wherein the film is formed before the substrate is provided on a second substrate.

(16) The method for manufacturing a light-emitting device according to (14), further comprising forming, on a second surface of the substrate, a plurality of lenses as a part of the substrate on which light emitted from the light-emitting devices is incident.

(17) The method for manufacturing a light-emitting device according to (16), wherein the lens is formed before the film is formed.

(18) The method for manufacturing a light-emitting device according to (16), wherein the lens is formed after the film is formed.

(19) The method for manufacturing a light-emitting device according to (16), wherein the lenses include at least one of a concave lens, a convex lens, and a flat lens.

(20) The method for manufacturing a light-emitting device according to (19), wherein the concave lens is formed by forming a convex portion at the second surface of the second substrate and processing the convex portion into a concave portion.

(21) The method for manufacturing a light-emitting device according to (19), wherein the convex lens is formed by forming a convex portion at the second surface of the second substrate.

(22) A method for manufacturing a light-emitting device comprising:

sequentially forming a plurality of light-emitting elements and a plurality of electrodes on a first surface of a substrate;

forming a film on the first surface of the substrate to surround the light-emitting elements; and

providing the substrate on the second substrate after forming the film.

(23) The method for manufacturing a light-emitting device according to (22), wherein when the first surface is an upper surface of the substrate, the uppermost part of an upper surface of the film is formed to be lower than an upper surface of the electrode.

(24) The method for manufacturing a light-emitting device according to (22), further comprising forming, on a second surface of the substrate, a plurality of lenses as a part of the substrate on which light emitted from the light-emitting elements is incident.

### REFERENCE SIGNS LIST

1 Light-emitting device

2 Image-sensing device

3 Control device

11 Light-emitting unit

12 Driving circuit

13 Power supply circuit

14 Light-emitting side optical system

21 Image sensor

22 Image processing unit

23 Image-sensing side optical system

31 Distance measuring unit

41 LD chip

42 LDD substrate

43 Mounting substrate

44 Heat dissipation substrate

45 Correction lends holder

46 Correction lens

47 Wiring

48 Bump

51 Substrate

52 Laminated film

53 Light-emitting element

54 Anode electrode

55 Cathode electrode

56 Insulating film

57 Organic film

58 Inorganic film

59 Metal film

61 Substrate

62 Connection pad

63 Underfill film

64 Void

65 Insulating film

66 Heat sink

67 Conductive adhesive

71 Lens

72 Resin film

73 Adhesive

74 Glass substrate

75 Mounting device

81 Resist film

82 Resist film

83 Convex portion

84 Hard mask layer

85 Concave portion

91 Hard mask layer

92 Opening portion

93 First hard mask layer

94 Second hard Mask layer

95 Opening portion

96 Concave portion

1. A light-emitting device comprising:
a substrate;
a plurality of light-emitting elements and a plurality of electrodes sequentially provided on a first surface of the substrate; and
a film provided on the first surface of the substrate to surround the light-emitting elements, wherein
in a state where the first surface is a bottom surface of the substrate, the lowermost part of a bottom surface of the film is provided in a higher position than a bottom surface of the electrode.

2. The light-emitting device according to claim 1, further comprising a plurality of lenses which are provided on a second surface of the substrate as a part of the substrate and on which light emitted from the light-emitting elements is incident.

3. A method for manufacturing the light-emitting device according to claim 2, wherein the lenses include at least one of a concave lens, a convex lens, and a flat lens.

4. The light-emitting device according to claim 1, wherein the substrate is a semiconductor substrate including gallium (Ga) and arsenic (As).

5. The light-emitting device according to claim 1, wherein the film surrounds the light-emitting elements through an insulating film.

6. The light-emitting device according to claim 1, wherein the film is an insulating film.

7. The light-emitting device according to claim 1, wherein the film is an organic film or an inorganic film.

8. The light-emitting device according to claim 1, wherein the film is a metal film.

9. The light-emitting device according to claim 1, wherein the film has a thermal conductivity higher than that of the substrate.

10. The light-emitting device according to claim 1, wherein the substrate is provided on a second substrate, and the film is not in contact with the second substrate.

11. The light-emitting device according to claim 10, wherein the second substrate is a semiconductor substrate including silicon (Si).

12. The light-emitting device according to claim 10, further comprising a fill film provided between the film and the second substrate.

13. The light-emitting device according to claim 10, further comprising a heat sink and a conductive adhesive provided between the heat sink and the film.

14. A method for manufacturing a light-emitting device comprising:
sequentially forming a plurality of light-emitting elements and a plurality of electrodes on a first surface of a substrate; and
forming a film on the first surface of the substrate to surround the light-emitting elements, wherein
in a state where the first surface is an upper surface of the substrate, the uppermost part of an upper surface of the film is formed to be lower than an upper surface of the electrode.

15. The method for manufacturing a light-emitting device according to claim 14, further comprising forming, on a second surface of the substrate, a plurality of lenses as a part of the substrate on which light emitted from the light-emitting devices is incident.

16. The method for manufacturing a light-emitting device according to claim 15, wherein the lenses include at least one of a concave lens, a convex lens, and a flat lens.

17. The method for manufacturing a light-emitting device according to claim 16, wherein the convex lens is formed by forming a convex portion at the second surface of the second substrate.

18. A method for manufacturing a light-emitting device comprising:
sequentially forming a plurality of light-emitting elements and a plurality of electrodes on a first surface of a substrate;
forming a film on the first surface of the substrate to surround the light-emitting elements; and
providing the substrate on the second substrate after forming the film.

19. The method for manufacturing a light-emitting device according to claim 18, wherein when the first surface is an upper surface of the substrate, the uppermost part of the upper surface of the film is formed to be lower than an upper surface of the electrode.

20. The method for manufacturing a light-emitting device according to claim 18, further comprising forming, on a second surface of the substrate, a plurality of lenses as a part of the substrate on which light emitted from the light-emitting elements is incident.
